(19) United States
(12) Patent Application Publication
(10) Pub. No.: US 2011/0256422 A1
(43) Pub. Date: Oct. 20, 2011

(54) MEROCYANINES FOR PRODUCING PHOTOACTIVE LAYERS FOR ORGANIC SOLAR CELLS AND ORGANIC PHOTODETECTORS

(75) Inventors: Helmut Reichelt, Neustadt (DE); Jae Hyung Hwang, Mannheim (DE); Ruedinger Sens, Ludwigshafen (DE); Jan Schoeneboom, Mannheim (DE); Peter Erk, Frankenthal (DE); Ingmar Bruder, Ludwigshafen (DE); Antti Ojala, Ludwigshafen (DE); Frank Wuerthner, Hoechberg (DE); Klaus Meerholz, Roesrath (DE)

(73) Assignee: BASF SE, Ludwigshafen (DE)

(21) Appl. No.: 13/126,868

(22) PCT Filed: Oct. 30, 2009
(86) PCT No.: PCT/EP2009/064331

§ 371 Date: Jul. 6, 2011

(30) Foreign Application Priority Data
Oct. 31, 2008 (EP) 08168116.5

(51) Int. Cl. B05D 5/12; B32B 9/00; C09K 3/00; B82Y 30/00

(52) U.S. Cl. 428/704; 252/582; 427/74; 977/734

(57) ABSTRACT

The present invention relates to the use of mixtures which comprise, as components K1), one or more merocyanines selected from the group of the compounds of the general formulae I, IIa, IIb, IIIa, IIIb, IIIc, IIId and IIIe, as defined in more detail in the description, as an electron donor or electron acceptor, and, as component K2), one or more compounds which, with respect to component K1), act correspondingly as an electron acceptor or electron donor, for producing photoactive layers for organic solar cells and organic photodetectors, to a process for producing photoactive layers, corresponding solar cells and organic photodetectors, and to mixtures which comprise, as components, one or more compounds of the general formulae I, IIa, IIb, IIIa, IIIb, IIIc, IIId and/or IIIe of component K1, as defined in more detail in the description, and one or more compounds of component K2.

The present invention relates to the use of mixtures comprising, as components, K1) one or more compounds selected from the group of the compounds of the general formulae

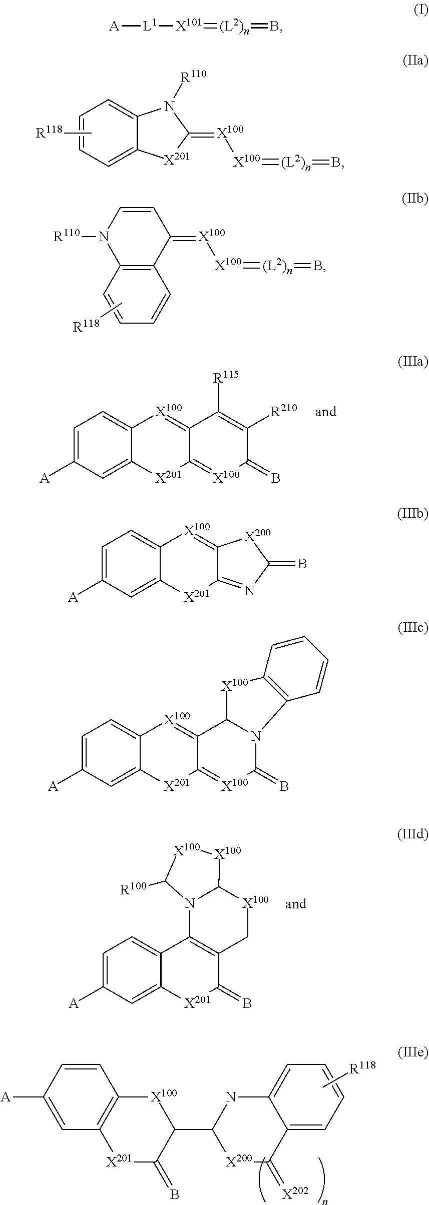

as an electron donor or electron acceptor, in which
A is NR¹¹⁰₂, where both R¹¹⁰ radicals together with the nitrogen atom to which they are bonded may form a five- or six-membered saturated ring, or one of the R¹¹⁰ radicals forms, with the carbon atom of the benzene ring in the a position to the carbon atom which bears the NR¹¹⁰₂ group, a five- or six-membered saturated ring, SR¹¹⁰ or OR¹¹⁰,
B is O, S, N—CN, N—R¹¹⁰, C(CN)₂, C(CO₂R¹¹⁰), C(CN)COR¹¹⁰, C(CN)CO₂R¹¹⁰, C(CN)CONR¹⁰⁰₂ or a moiety selected from the group of

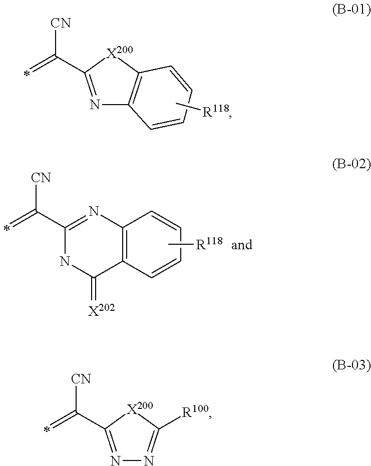

in which *, in the case of the compounds of the formulae I, IIa and IIb, denotes the bond to L², and, in the case of the compounds of the formulae IIIa and IIIb, the bond to the remaining part of the molecule,
L¹ is a divalent aryl or hetaryl radical,
L² is a divalent, optionally singly or multiply fused carbo- or heterocycle which is π-conjugated firstly to B, and secondly via the X¹⁰⁰ or X¹⁰¹ units and the remaining part of the molecule to A, or a

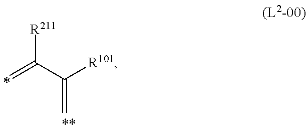

moiety in which * and ** denote the bond firstly to the corresponding X¹⁰¹ or X¹⁰⁰ unit, and secondly to B,
n is 0 or 1,
X¹⁰⁰ is CH, N or C(CN),
X¹⁰¹ is CH, N, C(CN) or X¹⁰¹ and L² together form a

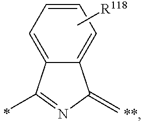

moiety in which * and ** denote the bond firstly to the corresponding L¹ unit, and secondly to B,
X²⁰⁰ is O, S, SO₂ or NR¹¹⁰,
X²⁰¹ is O, S, SO₂, NR¹¹⁰ or CR¹¹¹₂,
X²⁰² is twice H, O or S,
R¹⁰⁰ is alkyl, C₁-C₆-alkylene-COO-alkyl, C₁-C₆-alkylene-O—CO-alkyl, C₁-C₆-alkylene-O—CO—O-alkyl, cycloalkyl, arylalkyl or aryl,
R¹¹⁰ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl or aryl,
R¹⁰¹ is alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl or hetaryl,
R¹¹¹ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl or hetaryl,
R¹¹⁵ is H, alkyl, partly fluorinated or perfluorinated alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, NHCO—R¹⁰⁰ or N(CO—R¹⁰⁰)₂,
R¹¹⁸ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, OR¹¹⁰, SR¹¹⁰, hetaryl, halogen, NO₂ or CN
R²¹⁰ is H or CN,
R²¹¹ is H, CN or SCN,
   where the carbon chains of the alkyl and cycloalkyl radicals may be interrupted by one or two nonadjacent oxygen atoms, the R¹¹⁵ and R²¹⁰ radicals in formula IIIa together may form a fused benzene ring optionally substituted by R¹¹⁸, in the case of the definition CH for X¹⁰⁰ in formula IIId the R¹⁰⁰ radical may form an optionally R¹¹⁸-substituted benzofusion to this carbon atom, and the aforementioned variables, where they occur more than once, may be the same or different,
      and
K2) one or more compounds which, with respect to component K1), act correspondingly as an electron acceptor or electron donor
   for producing photoactive layers for organic solar cells and organic photodetectors, to a process for producing photoactive layers, corresponding solar cells and organic photodetectors, and to mixtures which comprise, as components, one or more compounds of the general formulae I, IIa, IIb, IIIa, IIIb, IIIc, IIId and/or IIIe of component K1, and one or more compounds of component K2.

It is expected that, in the future, not only the conventional inorganic semiconductors but increasingly also organic semiconductors based on low molecular weight or polymeric materials will be used in many fields of the electronics industry. In many cases, these organic semiconductors have advantages over the classical inorganic semiconductors, for example better substrate compatibility and better processability of the semiconductor components based on them. They allow processing on flexible substrates and enable their interface orbital energies to be adjusted precisely to the particular application range by the methods of molecular modeling. The significantly reduced costs of such components have brought a renaissance to the field of research of organic electronics. Organic electronics is concerned principally with the development of new materials and manufacturing processes for the production of electronic components based on organic semiconductor layers. These include in particular organic field-effect transistors (OFETs) and organic light-emitting diodes (OLEDs; for example for use in displays), and organic photovoltaics.

The direct conversion of solar energy to electrical energy in solar cells is based on the internal photoeffect of a semiconductor material, i.e. the generation of electron hole pairs by absorption of photons and the separation of the negative and positive charge carriers at a p-n transition or a Schottky contact. The photovoltage thus generated can bring about a photocurrent in an external circuit, through which the solar cell delivers its power.

The semiconductor can absorb only those photons which have an energy which is greater than its band gap. The size of the semiconductor band gap thus determines the proportion of sunlight which can be converted to electrical energy. It is expected that, in the future, organic solar cells will outperform the classical solar cells based on silicon owing to lower costs, a lower weight, the possibility of producing flexible and/or colored cells, the better possibility of fine adjustment of the band gap. There is thus a great demand for organic semiconductors which are suitable for producing organic solar cells.

In order to utilize solar energy as effectively as possible, organic solar cells normally consist of two absorbing materials with different electron affinity or different ionization behavior. In that case, one material functions as a p-conductor (electron donor), the other as an n-conductor (electron acceptor). The first organic solar cells consisted of a two layer system composed of a copper phthalocyanine as a p-conductor and PTCBI as an n-conductor, and exhibited an efficiency of 1%. In order to utilize as many incident photons as possible, relatively high layer thicknesses are used (e.g. 100 nm). In order to generate current, the excited state generated by the absorbed photons must, however, reach a p-n junction in order to generate a hole and an electron, which then flows to the anode and cathode. Most organic semiconductors, however, have only diffusion lengths for the excited state of up to 10 nm. Even the best production processes known to date allow the distance over which the excited state has to be transmitted to be reduced to no less than from 10 to 30 nm.

More recent developments in organic photovoltaics have been in the direction of the so-called “bulk heterojunction”: in this case, the photoactive layer comprises the acceptor and donor compound(s) as a bicontinuous phase. As a result of photoinduced charge transfer from the excited state of the donor compound to the acceptor compound, owing to the spatial proximity of the compounds, a rapid charge separation compared to other relaxation procedures takes place, and the holes and electrons which arise are removed via the corresponding electrodes. Between the electrodes and the photoactive layer, further layers, for example hole or electron transport layers, are often applied in order to increase the efficiency of such cells.

To date, the donor materials used in such bulk heterojunction cells have usually been polymers, for example polyvinylphenylenes or polythiophenes, or dyes from the class of the phthalocyanines, e.g. zinc phthalocyanine or vanadyl phthalocyanine, and the acceptor materials used have been fullerene and fullerene derivatives and also various perylenes. Photoactive layers composed of the donor/acceptor pairs poly(3-hexylthiophene) (“P3HT”)/[6,6]-phenyl-C₆₁-butyric acid methyl ester (“PCBM”), poly(2-methoxy-5-(3,7-dimethyloctyloxy)-1,4-phenylenevinylene) (“OC₁C₁₀-PPV”)/PCBM and zinc phthalocyanine/fullerene have been and are being researched intensively.

It was thus an object of the present invention to provide further photoactive layers for use in electronic components, especially in organic solar cells and organic photodetectors, which are easy to produce and have a sufficient efficiency for the conversion of light energy to electrical energy in industrial applications.

Accordingly, the use described at the outset of mixtures for producing photoactive layers for organic solar cells and organic photodetectors has been found.

The definitions of the variables listed above are explained in detail hereinafter and should be understood as follows.

Halogen denotes fluorine, chlorine, bromine and iodine, especially fluorine and chlorine.

Alkyl is understood to mean substituted or unsubstituted C₁-C₂₀-alkyl radicals. Preference is given to C₁- to C₁₀-alkyl radicals, particular preference to C₁- to C₆-alkyl radicals. The alkyl radicals may be either straight-chain or branched. In addition, the alkyl radicals may be substituted by one or more substituents selected from the group consisting of C₁-C₂₀-alkoxy, halogen, preferably F, and C₆-C₃₀-aryl which may in turn be substituted or unsubstituted. Suitable aryl substituents and suitable alkoxy and halogen substituents are specified hereinafter. Examples of suitable alkyl groups are methyl, ethyl, propyl, butyl, pentyl, hexyl, heptyl and octyl, and C₆-C₃₀-aryl-, C₁-C₂₀-alkoxy- and/or halogen-substituted, especially F-substituted derivates of the alkyl groups mentioned, for example CF₃. This includes both the n-isomers of the radicals mentioned and branched isomers such as isopropyl, isobutyl, isopentyl, sec-butyl, tert-butyl, neopentyl, 3,3-dimethylbutyl, 3-ethylhexyl, etc. Preferred alkyl groups are methyl, ethyl, tert-butyl and CF₃.

Cycloalkyl is understood to mean substituted or unsubstituted C₃-C₂₀-alkyl radicals. Preference is given to C₃- to C₁₀-alkyl radicals, particular preference to C₃- to C₈-alkyl radicals. The cycloalkyl radicals may bear one or more of the substituents mentioned for the alkyl radicals. Examples of suitable cyclic alkyl groups (cycloalkyl radicals), which may likewise be unsubstituted or substituted by the radicals mentioned above for the alkyl groups, are cyclopropyl, cyclobutyl, cyclopentyl, cyclohexyl, cycloheptyl, cyclooctyl, cyclononyl and cyclodecyl. They may optionally also be polycyclic ring systems, such as decalinyl, norbornyl, bornanyl or adamantyl.

Alkyl which is interrupted by one or two nonadjacent oxygen atoms includes, for example, 3-methoxyethyl, 2- and 3-methoxypropyl, 2-ethoxyethyl, 2- and 3-ethoxypropyl, 2-propoxyethyl, 2- and 3-propoxypropyl, 2-butoxyethyl, 2- and 3-butoxypropyl, 3,6-dioxaheptoyl and 3,6-dioxaoctyl.

Suitable aryls are C₆-C₃₀-aryl radicals which are derived from monocyclic, bicyclic or tricyclic aromatics which do not comprise any ring heteroatoms. When they are not monocyclic systems, the term “aryl” for the second ring may also include the saturated form (perhydro form) or the partly unsaturated form (for example the dihydro form or tetrahydro form), provided that the particular forms are known and stable. This means that the term “aryl” in the present invention also encompasses, for example, bicyclic or tricyclic radicals in which either both or all three radicals are aromatic, and bicyclic or tricyclic radicals in which only one ring is aromatic, and also tricyclic radicals in which two rings are aromatic. Examples of aryl are: phenyl, naphthyl, indanyl, 1,2-dihydronaphthenyl, 1,4-dihydronaphthenyl, indenyl, anthracenyl, phenanthrenyl or 1,2,3,4-tetrahydronaphthyl. Particular preference is given to C₅-C₁₀-aryl radicals, for example phenyl or naphthyl, very particular preference to C₆-aryl radicals, for example phenyl.

The aryl radicals may be unsubstituted or substituted by one or more further radicals. Suitable further radicals are selected from the group consisting of C₁-C₂₀-alkyl, C₆-C₃₀-aryl and substituents with donor or acceptor action, suitable substituents with donor or acceptor action being:

C₁-C₂₀-alkoxy, C₆-C₃₀-aryloxy, C₁-C₂₀-alkylthio, C₆-C₃₀-arylthio, Si(R)₃, halogen radicals, halogenated C₁-C₂₀-alkyl radicals, carbonyl (—CO(R)), carbonylthio (—C═O(SR)), carbonyloxy (—C═O(OR)), oxycarbonyl (—OC═O(R)), thiocarbonyl (—SC═O(R)), amino (—NR₂), OH, pseudohalogen radicals, amido (—C═O(NR)), —N(R)C═O(R), phosphonate (—P(O) (OR)₂, phosphate (—OP(O) (OR)₂), phosphine (—PR₂), phosphine oxide (—P(O)R₂), sulfate (—OS(O)₂OR), sulfoxide (—S(O)R), sulfonate (—S(O)₂OR), sulfonyl (—S(O)₂R), sulfonamide (—S(O)₂NR₂), NO₂, boronic esters (—OB(OR)₂), imino (—C═NR₂)), borane radicals, stannane radicals, hydrazine radicals, hydrazone radicals, oxime radicals, nitroso groups, diazo groups, vinyl groups, (=sulfonate) and boronic acid groups, sulfoximines, alanes, germanes, boroximes and borazines.

Preferred substituents with donor or acceptor action are selected from the group consisting of:

C₁- to C₂₀-alkoxy, preferably C₁-C₆-alkoxy, more preferably ethoxy or methoxy; C₆-C₃₀-aryloxy, preferably C₆-C₁₀-aryloxy, more preferably phenyloxy; SiR₃, where the three R radicals are preferably each independently substituted or unsubstituted alkyl or substituted or unsubstituted phenyl, halogen radicals, preferably F, Cl, Br, more preferably F or Cl, most preferably F, halogenated C₁-C₂₀-alkyl radicals, preferably halogenated C₁-C₆-alkyl radicals, most preferably fluorinated C₁-C₆-alkyl radicals, e.g. CF₃, CH₂F, CHF₂ or C₂F₅; amino, preferably dimethylamino, diethylamino or diphenylamino; OH, pseudohalogen radicals, preferably CN, SCN or OCN, more preferably CN, —C(O)OC₁-C₄-alkyl, preferably —C(O)OMe, P(O)R₂, preferably P(O)Ph2, or SO₂R₂, preferably SO₂Ph.

R in the aforementioned groups is especially C₁-C₂₀-alkyl or C₆-C₃₀-aryl.

C₁-C₆-Alkylene-COO-alkyl, C₁-C₆-alkylene-O—CO-alkyl and C₁-C₆-alkylene-O—CO-β-alkyl derive from the above-described alkyl radicals through attachment to the C₁-C₆-alkylene-COO, C₁-C₆-alkylene-O—CO and C₁-C₆-alkylene-O—CO—O moieties, in which the C₁-C₆-alkylene units are preferably linear. Especially useful are C₂-C₄-alkylene units.

Arylalkyl is understood to mean especially aryl-C₁-C₂₀-alkyl groups. They derive from the alkyl and aryl groups detailed above through formal replacement of a hydrogen atom of the linear or branched alkyl chain by an aryl group. An example of a preferred arylalkyl group is benzyl.

Hetaryl is understood to mean unsubstituted or substituted heteroaryl radicals having from 5 to 30 ring atoms, which may be monocyclic, bicyclic or tricyclic, some of which can be derived from the aforementioned aryl, by virtue of at least one carbon atom in the aryl base skeleton being replaced by a heteroatom. Preferred heteroatoms are N, O and S. More preferably, the hetaryl radicals have from 5 to 13 ring atoms. The base skeleton of the heteroaryl radicals is especially preferably selected from systems such as pyridine and five-membered heteroaromatics such as thiophene, pyrrole, imidazole or furan. These base skeletons may optionally be fused to one or two six-membered aromatic radicals. Suitable fused heteroaromatics are carbazolyl, benzimidazolyl, benzofuryl, dibenzofuryl or dibenzothiophenyl. The base skeleton may be substituted at one, more than one or all substitutable positions, suitable substituents being the same as already specified under the definition of C₆-C₃₀-aryl. However, the hetaryl radicals are preferably unsubstituted. Suitable hetaryl radicals are, for example, pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl, and also the corresponding benzofused radicals, especially carbazolyl, benzimidazolyl, benzofuryl, dibenzofuryl or dibenzothiophenyl.

The divalent aryl or hetaryl radicals of the definition of L¹ derive from the aforementioned aryl and hetaryl radicals through the formal removal of a further hydrogen atom.

In the photoactive layers, component K1 may assume the role of the electron donor; correspondingly, component K2 is then assigned the role of the electron acceptor. Alternatively, component K1 may, however, also assume the role of the electron acceptor; correspondingly, component K2 then functions as the electron donor. The way in which the particular component acts depends on the energies of the HOMO and LUMO of component K1 in relation to the energies of the HOMO and LUMO of component K2. The compounds of component K1 are typically merocyanines, which typically appear as electron donors. This is the case especially when the components K2 used are rylene or fullerene derivatives, which then generally act as electron acceptors. However, these roles can be exchanged in the specific individual case. It should also be noted that component K2 may likewise obey the structural definition of component K1, such that one compound of the formula I, IIa, IIb, IIIa, IIIb, IIIc or IIIe may assume the role of the electron donor and another compound of the formula I, IIa, IIb, IIIa, IIIb, IIIc and IIIe the role of the electron acceptor.

Preferred compounds of the formulae I, IIa and/or IIb for use in accordance with the invention in component K1 are notable in that L² is a moiety selected from the group of

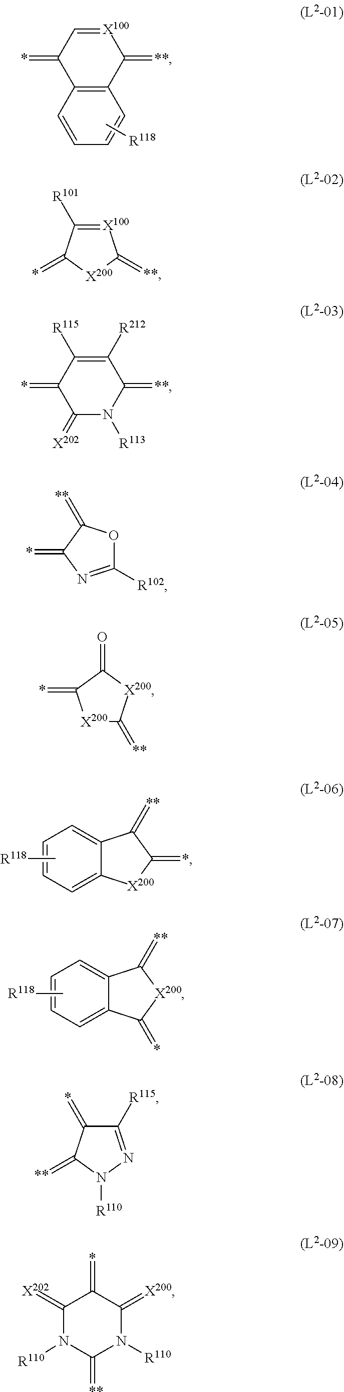

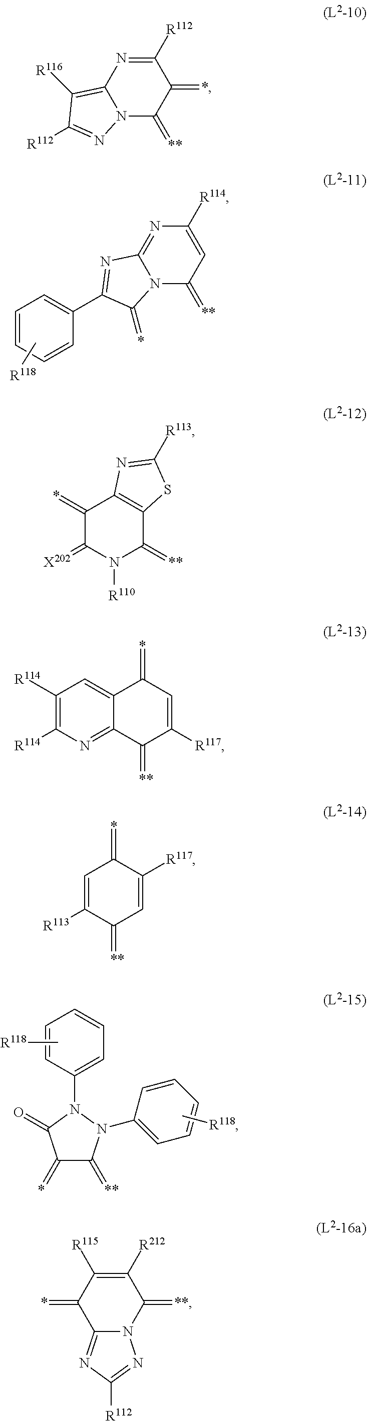

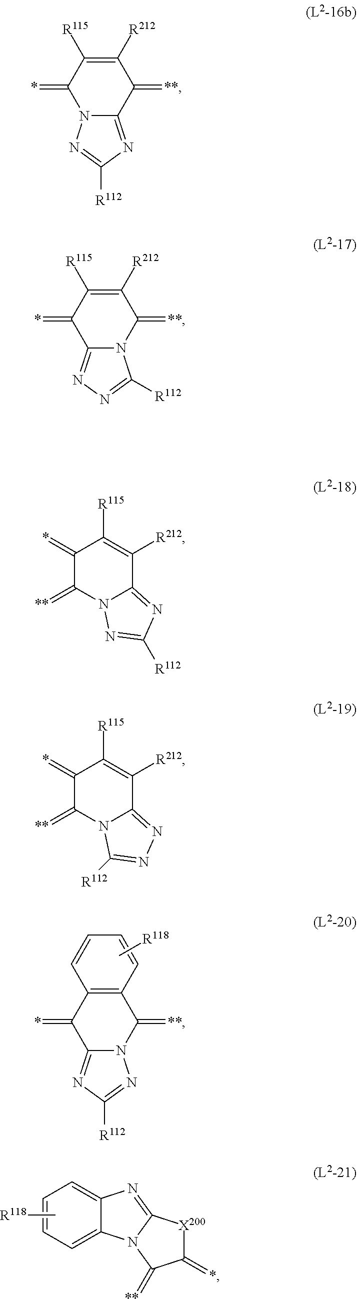

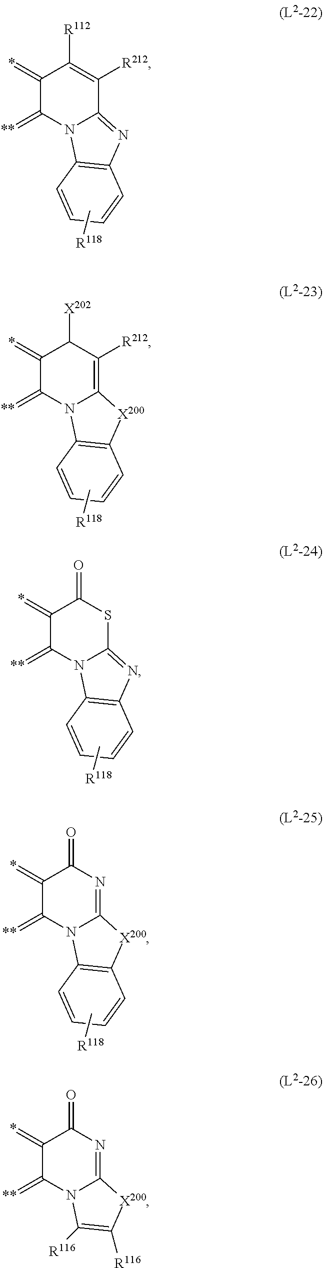

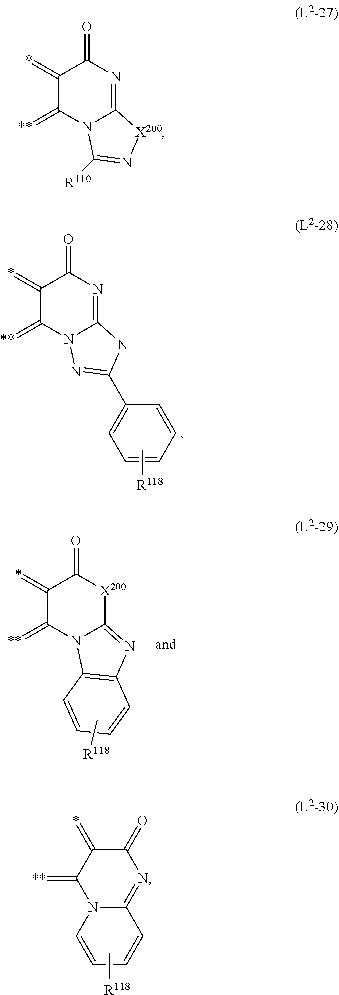

in which
R¹⁰² is arylalkyl, aryl or hetaryl,
R¹¹² is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, OR¹¹⁰ or SR¹¹⁰,
R¹¹³ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, hetaryl, NH-aryl, N(aryl)₂, NHCO—R¹⁰⁰ or N(CO—R¹⁰⁰)₂,
R¹¹⁴ is H, alkyl or partly fluorinated or perfluorinated alkyl, C₁-C₆-alkylene-COO-alkyl, C₁-C₆-alkylene-O—CO-alkyl or C₁-C₆-alkylene-O—CO—O-alkyl,
R¹¹⁶ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, CO₂R¹¹⁰ or CN
R¹¹⁷ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, OR¹¹⁰, SR¹¹⁰ halogen or hetaryl,
R²¹² is H, CN, CONR¹¹⁰ or COR¹⁰¹,
   and the remaining variables are each as defined at the outset, where the carbon chains of the alkyl and cycloalkyl radicals may be interrupted by one or two nonadjacent oxygen atoms, and the variables mentioned above and at the outset, where they occur more than once, may be the same or different.

Further mixtures for use with preference, also taking account of the above-described preferences, are notable in that component K2 comprises one or more compounds selected from the group of
a) fullerenes and fullerene derivatives,
b) polycyclic aromatic hydrocarbons and derivatives thereof, especially naphthalene and derivatives thereof, rylenes, especially perylene, terrylene and quaterrylene, and derivatives thereof, acenes, especially anthracene, tetracene, especially rubrene, pentacene and derivatives thereof, pyrene and derivatives thereof, coronene and hexabenzocoronene and derivatives thereof,
c) quinones, quinodimethanes and quinonediimines and derivatives thereof,
d) phthalocyanines and subphthalocyanines and derivatives thereof,
e) porphyrins, tetraazaporphyrins and tetrabenzoporphyrins and derivatives thereof,
f) thiophenes, oligothiophenes, fused thiophenes such as thienothiophene and bithienothiophene, and derivatives thereof,
g) thiadazoles and derivatives thereof,
h) carbazoles and triarylamines and derivatives thereof,
i) indanthrones, violanthrones and flavanthones and derivatives thereof and
j) fulvalenes, tetrathiafulvalenes and tetraselenafulvalenes and derivatives thereof.

More particularly, inventive use is found, also taking account of the above-described preferences, by mixtures which are notable in that component K2 comprises one or more fullerenes and/or fullerene derivatives.

Useful easily obtainable fullerene derivatives include especially compounds of the general formula k2

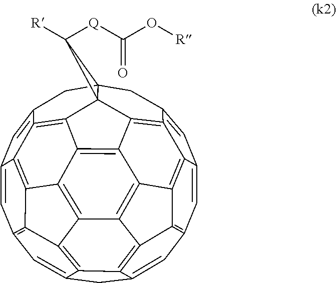

in which
Q is C₁-C₁₀-alkylene,
R′ is aryl or arylalkyl
   and
R″ is alkyl.

For definitions of aryl, arylalkyl and alkyl, reference is made to the statements already made above.

C₁-C₁₀-Alkylene is especially understood to mean a linear chain —(CH₂)ₘ— where m is 1, 2, 3, 4, 5, 6, 7, 8, 9 or 10.

More particularly, use is found in accordance with the invention by those fullerene derivatives in which R′ is a C₁-C₄-alkyl radical, especially a methyl radical, Q is a propylene chain —(CH₂)₃— and R″ is an optionally substituted phenyl or 2-thienyl. The fullerene derivative is preferably [6,6]-phenyl-C₆₁-butyric acid methyl ester (“PCBM”). Particular preference is given to using, also taking account of the above-mentioned preferences, mixtures in which component K2 comprises one or more fullerenes.

Possible fullerenes include C₆₀, C₇₀, C₇₆, C₈₀, C₈₂, CM, C₈₆, C₉₀ and C₉₄, especially C₆₀ and C₇₀. An overview of fullerenes which can be used in accordance with the invention is given, for example, by the monograph A. Hirsch, M. Brettreich, “Fullerenes: Chemistry and Reactions”, Wiley-VCH, Weinheim 2005.

More particularly, component K2 is a C60 fullerene of the formula k2

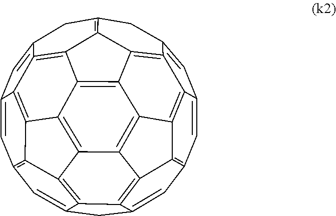

The mixtures for use in accordance with the invention are notable in that component K1 is present in a proportion of from 10 to 90% by mass, especially from 20 to 80% by mass, and component K2 in a proportion of from 90 to 10% by mass, especially from 80 to 20% by mass, the proportions of components K1 and K2, based in each case on the total mass of components K1 and K2, adding up to 100% by mass.

As a result of the preparation, it is possible in the individual case that not a compound of the formula I, IIa, IIb, IIIa or IIIb shown explicitly but a compound isomeric thereto is obtained, or else that mixtures of isomers are obtained. According to the invention, the isomeric compounds of the formulae I, IIa, IIb, IIIa, IIIb and the isomers of the corresponding preferred and mixtures of isomers shall accordingly also be included.

The synthesis of the compounds of the general formulae I, IIa, IIb, IIIa, IIIb, IIIc, IIId and IIIe are known to those skilled in the art or can be prepared based on known synthesis methods.

For example, with regard to corresponding syntheses, the following publications should be cited:
DE 195 02 702 A1, EP 416 434 A2, EP 509 302 A1, EP 291 853 A2, U.S. Pat. No. 5,147,845, U.S. Pat. No. 5,703,238;
“ATOP Dyes. Optimization of a Multifunctional Merocyanine Chromophore for High Refractive Index Modulation in Photorefractive Materials”, F. Würthner, S. Yao, J. Schilling, R. Wortmann, M. Redi-Abshiro, E. Mecher, F. Gallego-Gomez, K. Meerholz, J. Am. Chem. Soc. 2001, 123, 2810-2814;
“Merocyaninfarbstoffe im Cyaninlimit: eine neue Chromophorklasse für photorefraktive Materialien; Merocyanine Dyes in the Cyanine Limit: A New Class of Chromophores for Photorefractive Materials”, F. Würthner, R. Wortmann, R. Matschiner, K. Lukaszuk, K. Meerholz, Y. De Nardin, R. Bittner, C. Bräuchle, R. Sens, Angew. Chem. 1997, 109, 2933-2936; Angew. Chem. Int. Ed. Engl. 1997, 36, 2765-2768;
“Electrooptical Chromophores for Nonlinear Optical and Photorefractive Applications”, S. Beckmann, K.-H. Etzbach, P. Krämer, K. Lukaszuk, R. Matschiner, A. J. Schmidt, P. Schuhmacher, R. Sens, G. Seybold, R. Wortmann, F. Würthner, Adv. Mater. 1999, 11, 536-541;
“DMF in Acetic Anhydride: A Useful Reagent for Multiple-Component Syntheses of Merocyanine Dyes”, F. Würthner, Synthesis 1999, 2103-2113;
Ullmanns' Encyclopedia of industrial Chemistry, Vol. 16, 5th Edition (Ed. B. Elvers, S. Hawkins, G. Schulz), VCH 1990 in the chapter “Methine Dyes and Pigments”, p. 487-535 by R. Raue (Bayer AG).

Examples of L¹ units in the compounds of the general formula I are:

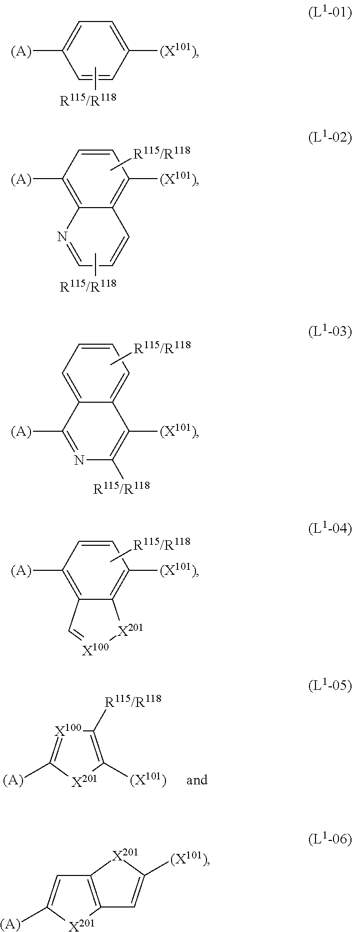

where (A) and (X¹⁰¹)) denote the particular bond to A and X¹⁰¹, and R¹¹⁵/R¹¹⁸ the substitution either by an R¹¹⁵ radical or an R¹¹⁸ radical. The variables here are each as already defined above.

Compounds usable in accordance with the invention of the general formula I are shown by way of example below:

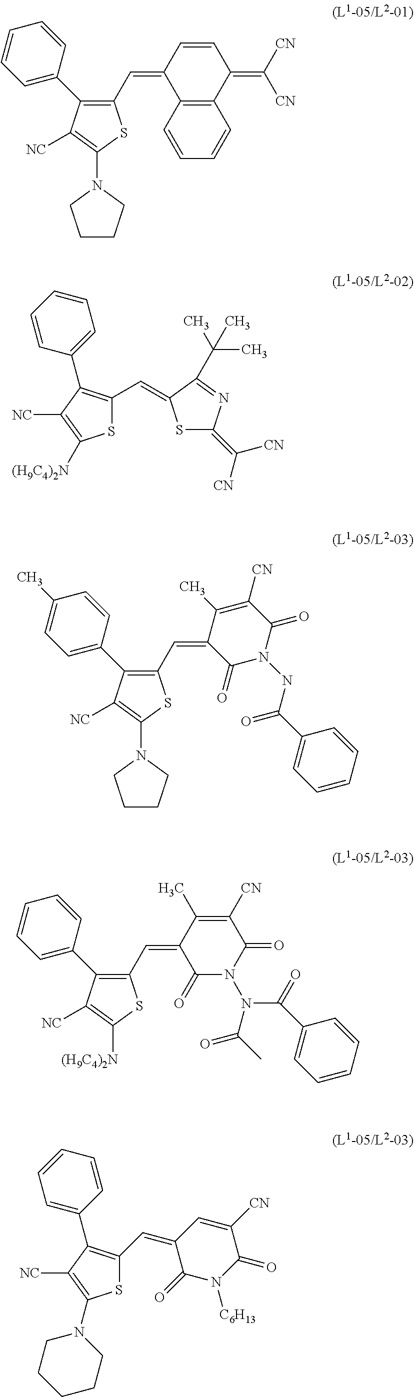

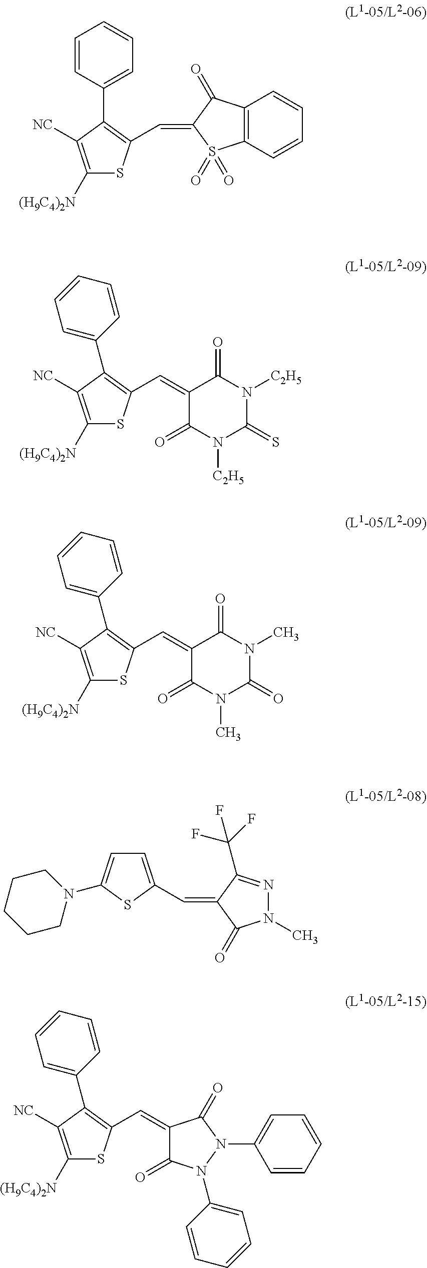

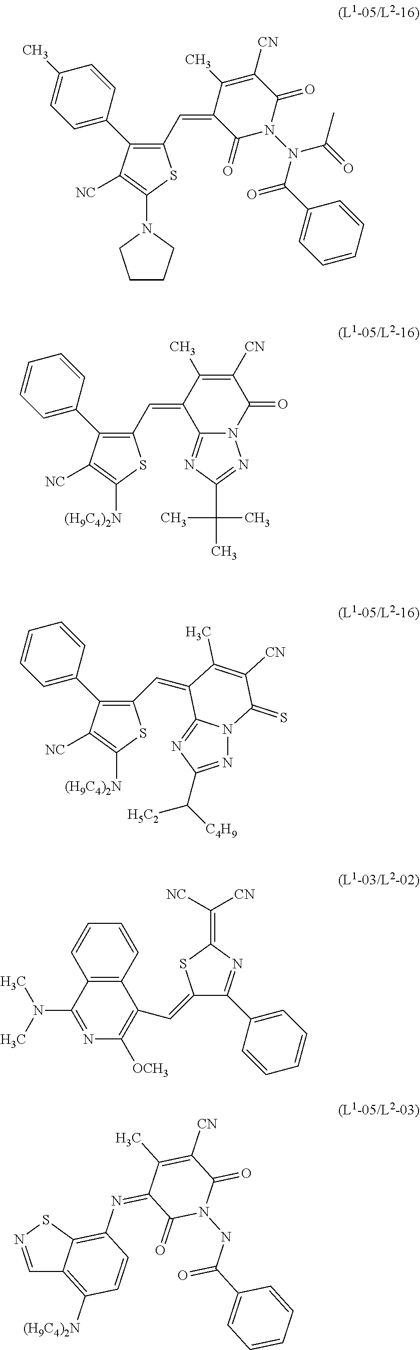

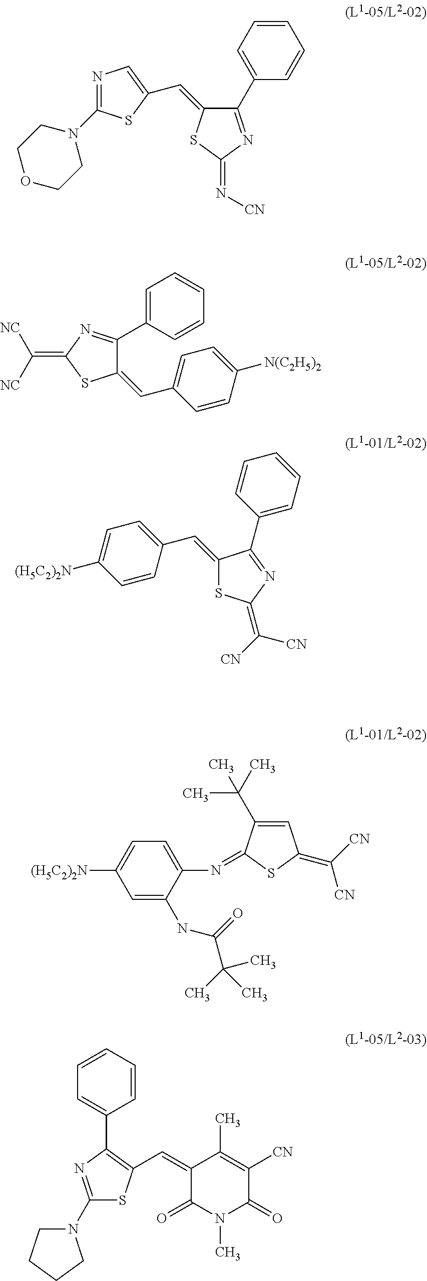

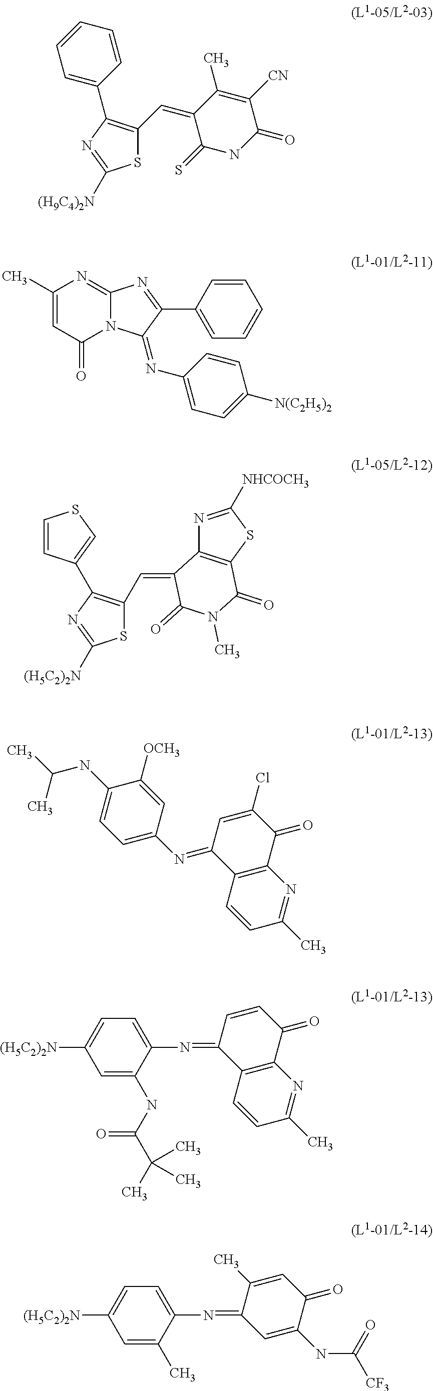

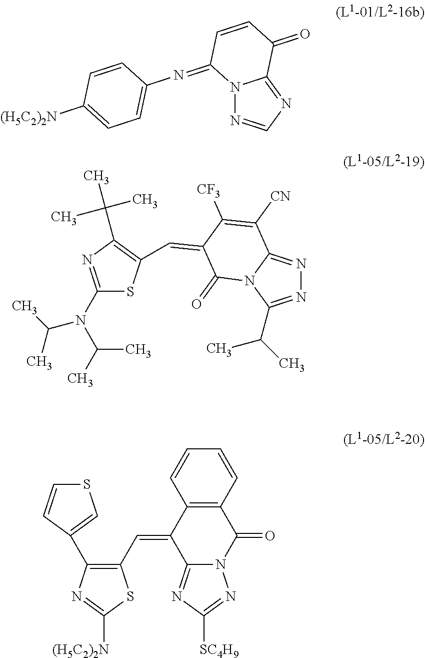

Further compounds of the formula I in which the L² unit is absent (n=0) are shown below:

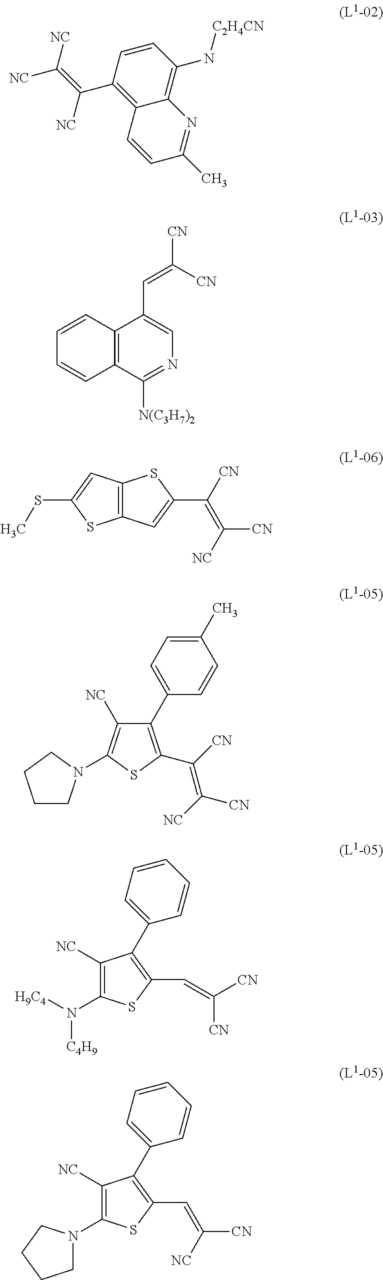

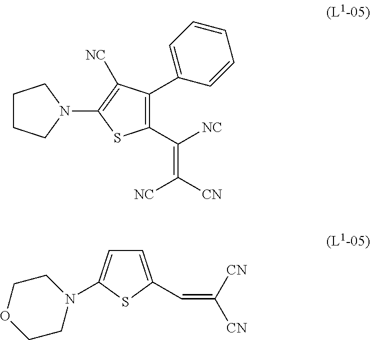

Compounds usable in accordance with the invention of the general formula IIa are shown by way of example below:

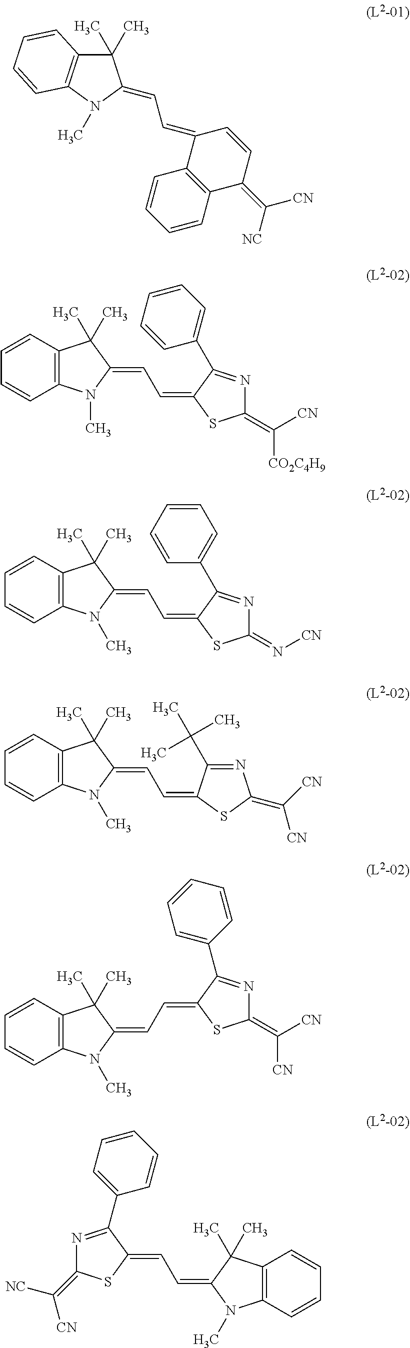

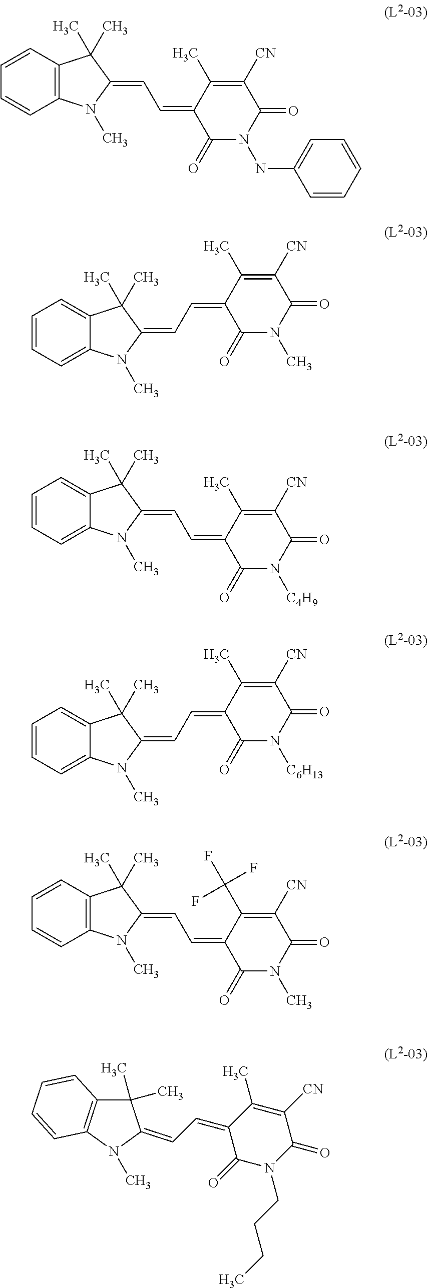

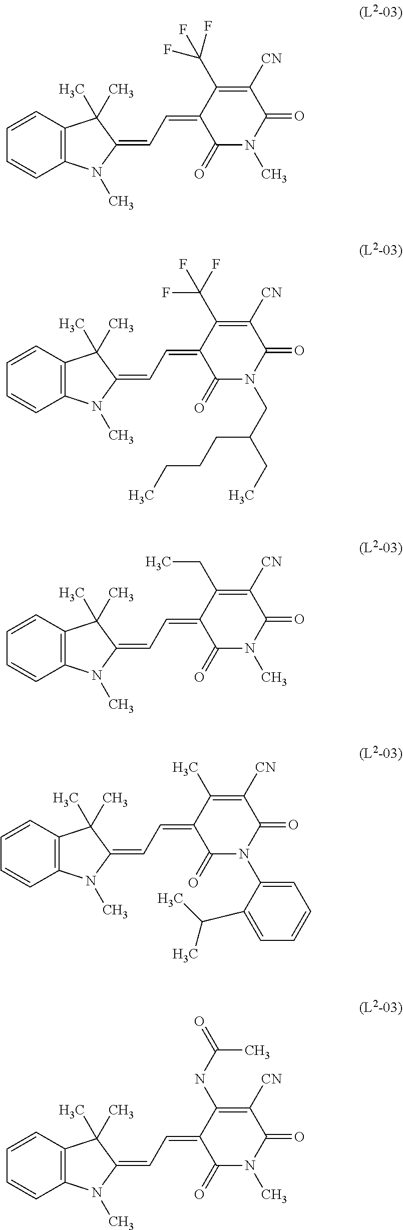

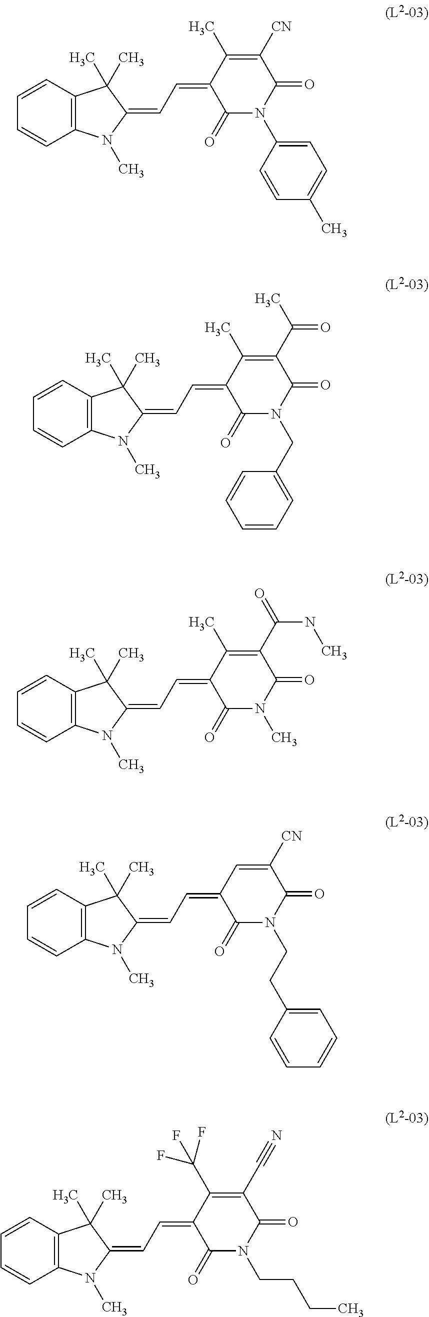

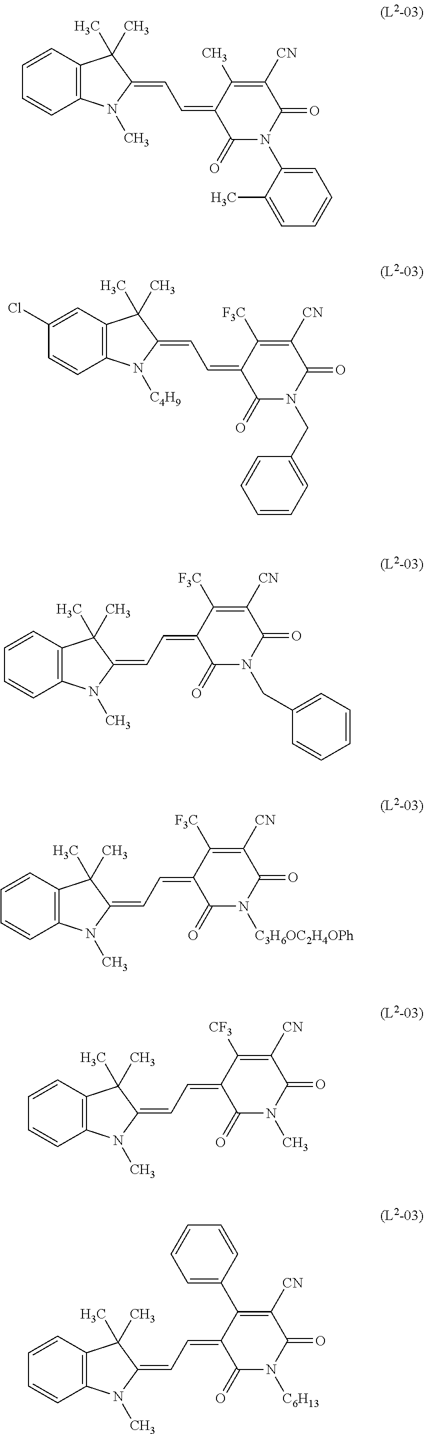

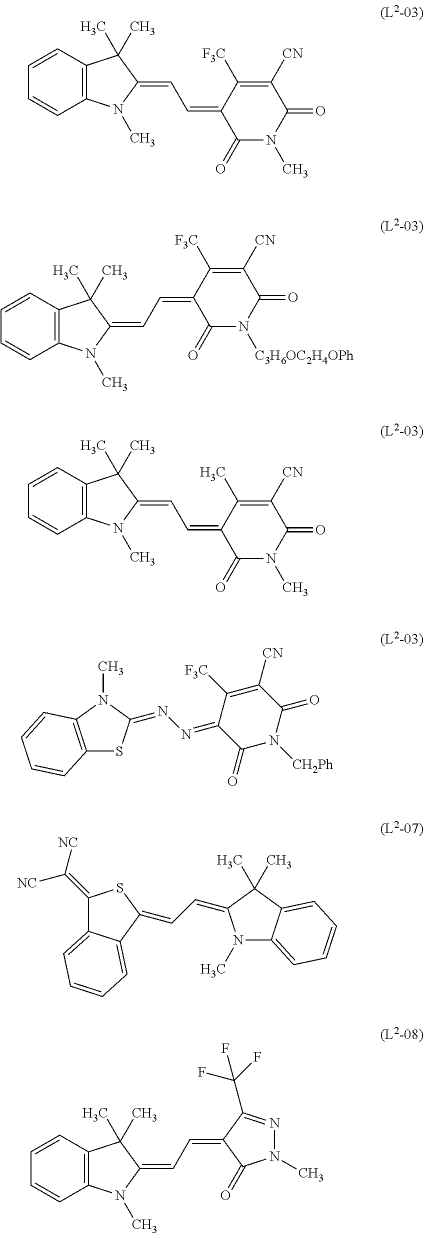

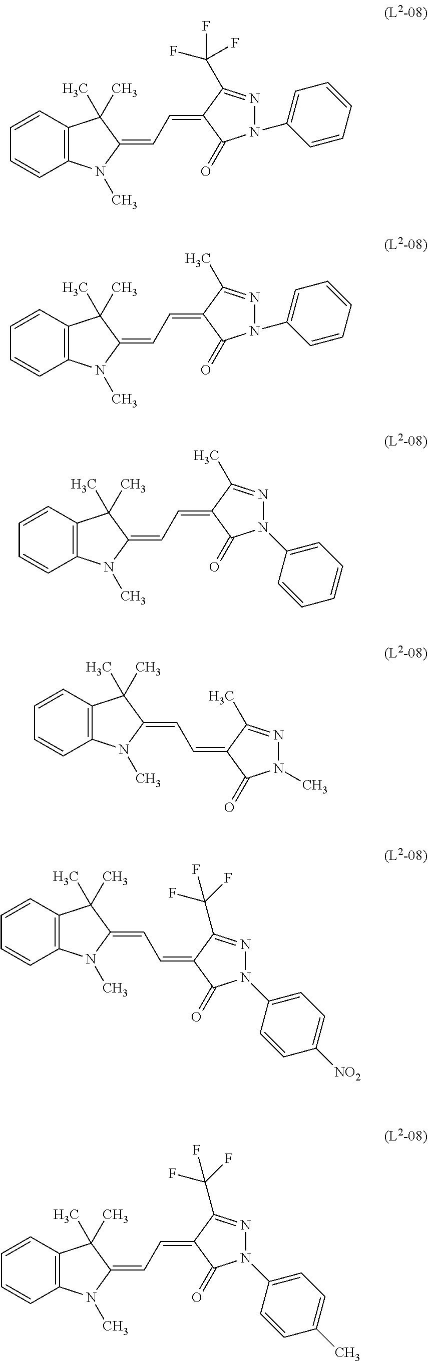

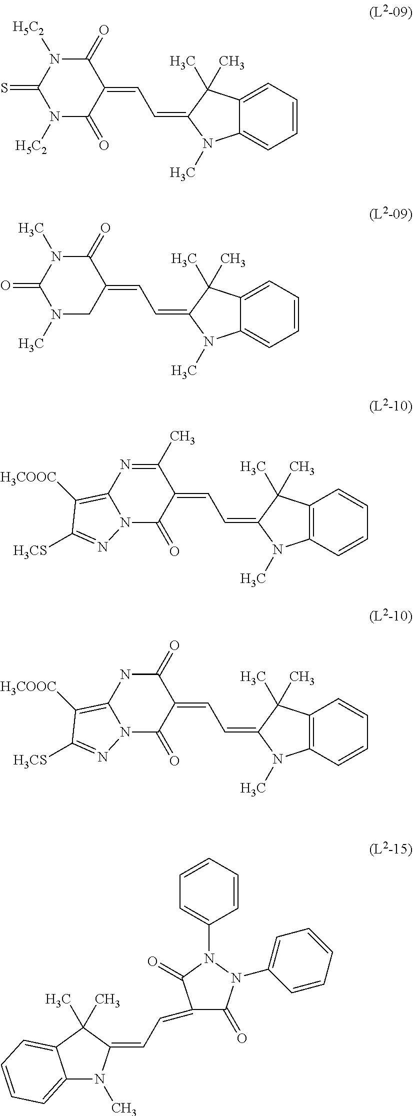

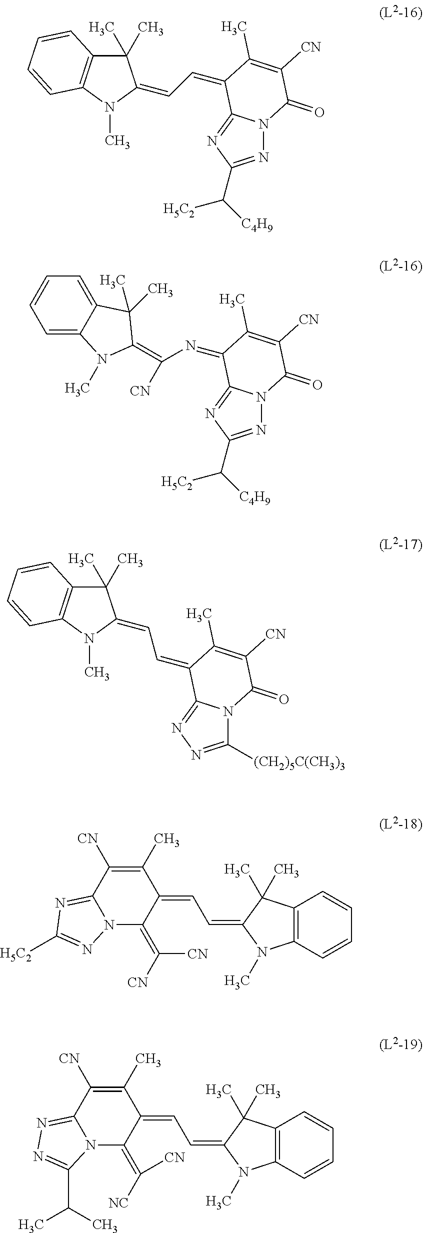

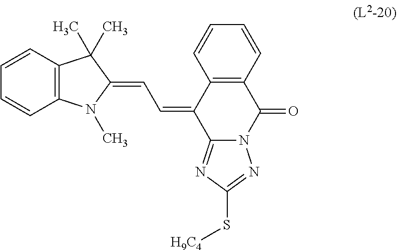

Further compounds of the formula IIa in which the L² unit is absent (n=0) are shown below:

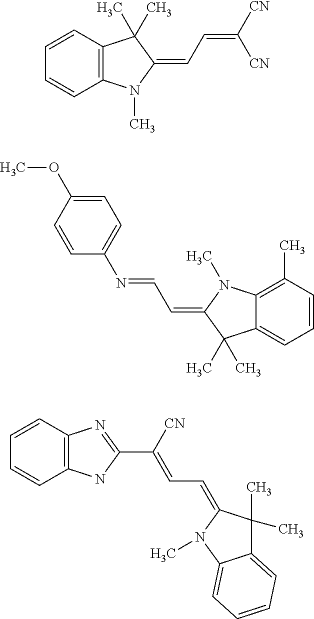

where the latter compound comprises a B-01 moiety.

A compound of the formula IIa with a L²-00 unit is shown below by way of example:

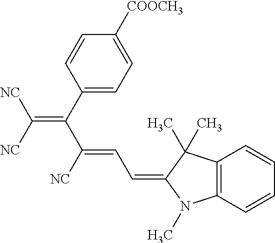

A compound of the formula IIb in which the L² unit is absent (n=0) is shown below:

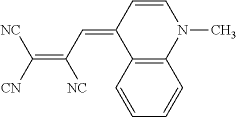

Examples of compounds of the formulae IIIa and IIIb are:

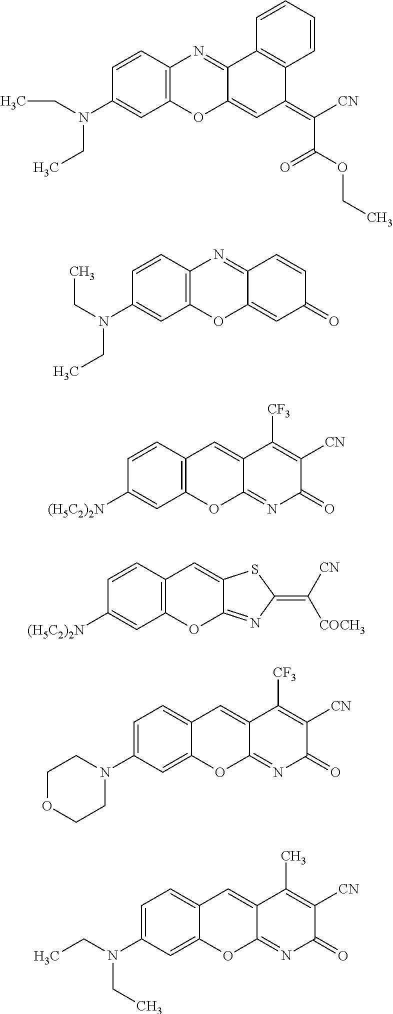

Examples of compounds of the Formula IIId are:

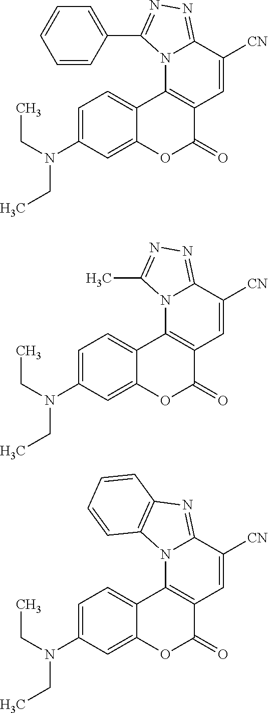

Examples of the compounds of Formula IIIe are:

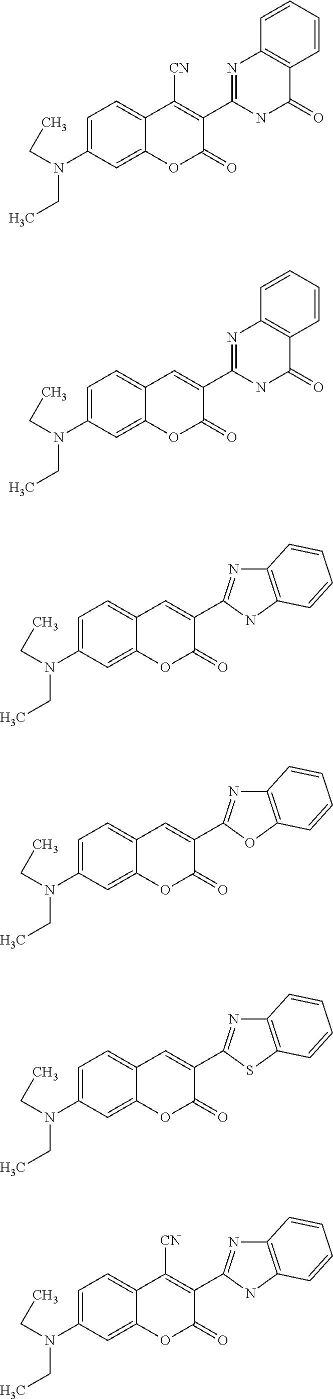

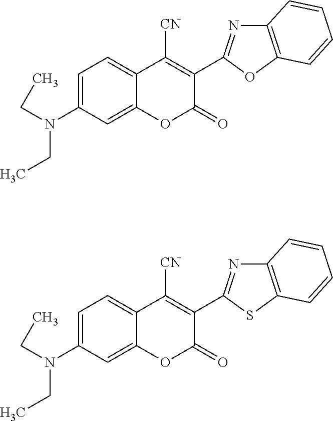

Moreover, in the context of the present invention, inter alia a process for producing photoactive layers is claimed, wherein one or more compounds of the general formulae I, IIa, IIb, IIIa, IIIb, IIIc, IIId and/or IIIe of component K1 shown at the outset, also taking account of their preferences, and one or more compounds of component K2, likewise taking account of their preferences, are deposited on a substrate successively, simultaneously or in alternating sequence by vacuum sublimation.

More particularly, the process is notable in that component K1 is present deposited on the substrate in a proportion of from 10 to 90% by mass, especially from 20 to 80% by mass, and component K2 in a proportion of from 90 to 10% by mass, especially from 80 to 20% by mass, where the proportions of components K1 and K2, based in each case on the total mass of components K1 and K2, add up to 100% by mass.

Also claimed in the context of the present invention are organic solar cells and organic photodetectors which comprise photoactive layers which have been produced using the above-described mixtures comprising components K1 and K2, or using the preferred embodiments of the mixtures which have likewise been described above. Organic solar cells usually have a layer structure and comprise generally at least the following layers: electrode, photoactive layer and counterelectrode. These layers are generally present on a substrate customary for this purpose. Suitable substrates are, for example, oxidic materials, for example glass, quartz, ceramic, SiO₂, etc., polymers, for instance polyvinyl chloride, polyolefins, e.g. polyethylene and polypropylene, polyesters, fluoropolymers, polyamides, polyurethanes, polyalkyl (meth)acrylates, polystyrene and mixtures and composites thereof, and combinations of the substrates listed above.

Suitable materials for one electrode are especially metals, for example the alkali metals Li, Na, K, Rb and Cs, the alkaline earth metals Mg, Ca and Ba, Pt, Au, Ag, Cu, Al, In, metal alloys, for example based on Pt, Au, Ag, Cu, etc., and specific Mg/Ag alloys, but additionally also alkali metal fluorides such as LiF, NaF, KF, RbF and CsF, and mixtures of alkali metal fluorides and alkali metals. The electrode used is preferably a material which essentially reflects the incident light. Examples include metal films composed of Al, Ag, Au, In, Mg, Mg/AI, Ca, etc.

The counterelectrode consists of a material essentially transparent toward incident light, for example ITO, doped ITO, ZnO, TiO₂, Cu, Ag, Au and Pt, the latter materials being present in correspondingly thin layers.

In this context, an electrode/counterelectrode shall be considered to be “transparent” when at least 50% of the radiation intensity in the wavelength range in which the photoactive layer absorbs radiation is transmitted. In the case of a plurality of photoactive layers, an electrode/counterelectrode shall be considered to be “transparent” when at least 50% of the radiation intensity in the wavelength ranges in which the photoactive layers absorb radiation is transmitted.

In addition to the photoactive layer, it is possible for one or more further layers to be present in the inventive organic solar cells and photodetectors, for example electron transporting layers (“ETLs”) and/or hole transporting layers (“HTLs”) and/or blocking layers, e.g. exciton blocking layers (“EBLs”) which typically do not absorb the incident light, or else layers which serve as charge transport layers and simultaneously improve the contacting to one or both electrodes of the solar cell. The ETLs and HTLs may also be doped, so as to give rise to cells of the p-i-n type, as described, for example, in the publication by J. Drechsel et al., Thin Solid Films 451-452 (2004), 515-517.

The construction of organic solar cells is additionally described, for example, in the documents WO 2004/083958 A2, US 2005/0098726 A1 and US 2005/0224905 A1, which are hereby fully incorporated by reference.

Photodetectors essentially have a structure analogous to organic solar cells, but are operated with suitable bias voltage which generates a corresponding current flow as a measurement response under the action of radiative energy.

The photoactive layers can be processed from solution. In this case, components K1 and K2 may already be dissolved together, but may also be present separately as a solution of component K1 and a solution of component K2, in which case the corresponding solutions are mixed just before application to the layer below. The concentrations of components K1 and K2 generally vary from a few g/l to a few tens of g/l of solvent.

Suitable solvents are all liquids which evaporate without residue and have a sufficient solubility for components K1 and K2. Useful examples include aromatic compounds, for example benzene, toluene, xylene, mesitylene, chlorobenzene or dichlorobenzene, trialkylamines, nitrogen-containing heterocycles, N,N-disubstituted aliphatic carboxamides, for instance dimethylformamide, diethylformamide, dimethylacetamide or dimethylbutyramide, N-alkyllactams, for instance N-methylpyrrolidone, linear and cyclic ketones, for instance methyl ethyl ketone, cyclopentanone or cyclohexanone, cyclic ethers, for instance tetrahydrofuran, or alcohols, for instance methanol, ethanol, propanol, isopropanol or butanol.

In addition, it is also possible for mixtures of the aforementioned solvents to find use.

Suitable methods for applying the inventive photoactive layers from the liquid phase are known to those skilled in the art. What is found to be advantageous here is especially processing by means of spin-coating, since the thickness of the photoactive layer can be controlled in a simple manner by the amount and/or concentration of the solution used, and also the rotation speed and/or rotation time. The solution is generally processed at room temperature.

However, components K1 and K2 are preferably deposited from the gas phase, especially by vacuum sublimation. Since the compounds of the formulae I, IIa, IIb, IIIa, IIIb, IIIc, IIId and IIIe can generally be purified by sublimation, it is possible to directly derive start parameters for the gas phase deposition therefrom. Typically, for the deposition, temperatures between 100 and 200° C. are employed, but they can also, according to the stability of the compounds of components K1 and K2, be increased up to a range from 300 to 400° C.

Also claimed in the context of the present invention are mixtures which comprise, as components, one or more of the compounds of the general formulae I, IIa, IIb, IIIa, IIIb, IIIc, IIId and/or IIIe of component K1 cited at the outset, also taking account of the preferences listed, and one or more compounds of component K2, likewise taking account of their preferences listed.

More particularly, the inventive mixtures are notable in that component K1 is present in a proportion of from 10 to 90% by mass, especially from 20 to 80% by mass, and component K2 in a proportion of from 90 to 10% by mass, especially from 80 to 20% by mass, where the proportions of components K1 and K2, based in each case on the total mass of components K1 and K2, add up to 100% by mass.

The invention will be illustrated in detail hereinafter by the examples, which should not be interpreted as a restriction of the scope of the invention.

### EXAMPLES

Compounds used as component K1 in the inventive photoactive layers:

Compounds of the General Formula I:

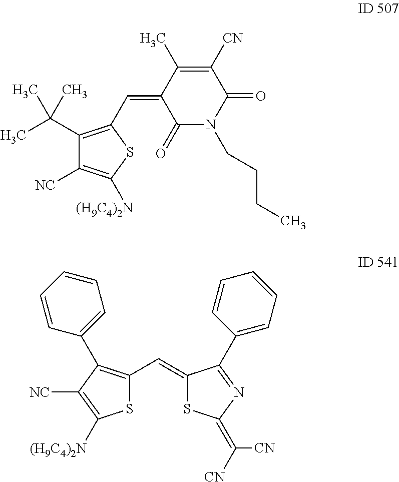

Compounds of the General Formula IIa:

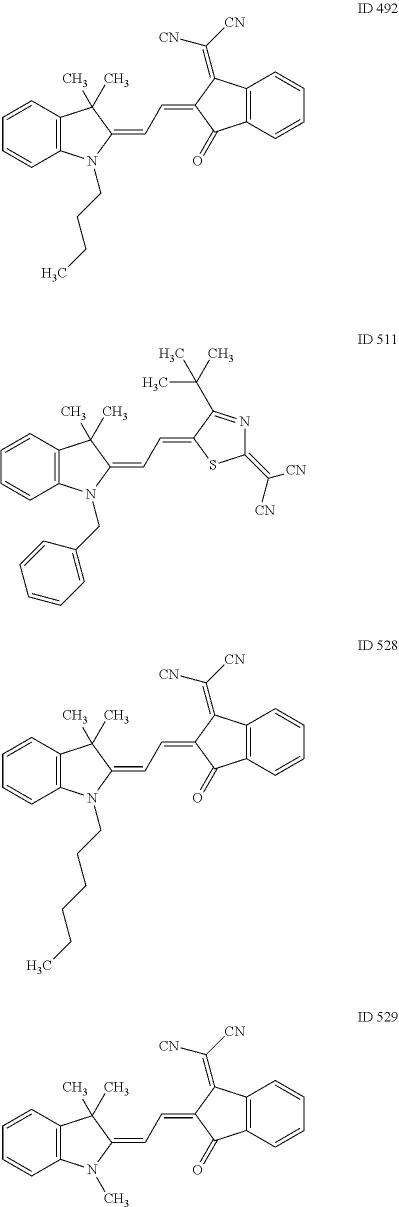

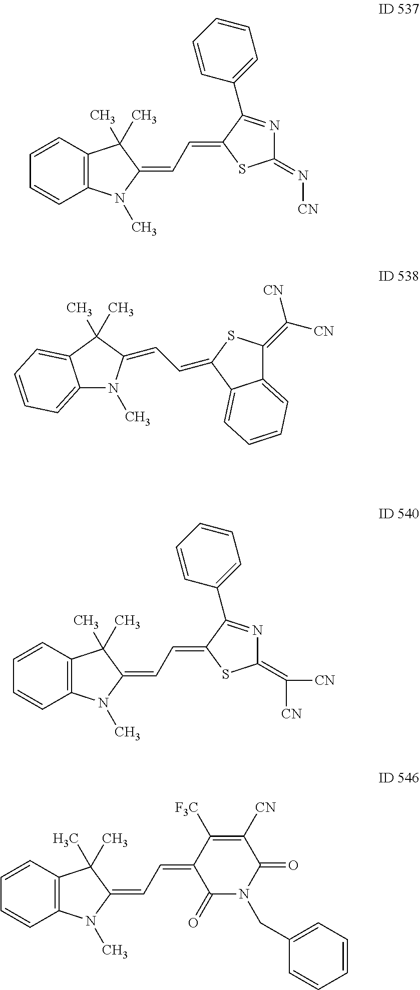

Construction of the Solar Cells:

A) Two Layer Structure:

The structure comprises the following layers:
16 metal electrode (cathode)
(15 optional EBL and/or ETL)
14 electron acceptor layer
13 electron donor layer
(12 optional HTL)
11 transparent electrode (anode)

Layer 11 is a transparent conductive layer, for example ITO, FTO or ZnO, which has optionally been pretreated, for example with oxygen plasma, UV/ozone purging, etc. This layer must, on the one hand, be sufficiently thin as to allow only low light absorption, but, on the other hand, thick enough to ensure satisfactory lateral charge transport within the layer. Typically, the thickness of the layer is 20-200 nm, and it is applied to a substrate such as glass or a flexible polymer (for example PET).

Layer 12 consists of one or more HTLs with a high ionization potential (>5.0 eV, preferably 5.5 eV). This layer may consist either of organic material, such as poly(3,4-ethylenedioxythiophene) doped with poly(styrenesulfonate)(PEDOT-PSS), or, for example, of Ir-DPBIC (tris-N,N′-diphenylbenzimidazol-2-ylideneiridium(III)), N,N′-diphenyl-N,N′-bis(3-methylphenyl)-1,1′-diphenyl-4,4′-diamine (α-NPD) and/or 2,2′,7,7′-tetrakis(N,N-di-p-methoxyphenylamine)-9,9′-spirobifluorene (spiro-MeOTAD), or of inorganic material, such as WO₃, MoO₃, etc. Typically, the layer thickness is 0-150 nm. In the case that layer 12 is formed from organic material, it can be admixed with a p-dopant whose LUMO energy is within the same energy range as or lower than the HOMO of the HTL. Such dopants are, for example, 2,3,5,6-tetrafluoro-7,7,8,8-tetracyanoquinodimethane (F₄TCNQ), WO₃, MoO₃, or the substances described in document WO 2007/071450 A1.

Layer 13 consists of the electron donor. Typically, the layer should be sufficiently thick that it absorbs a maximum amount of light, but on the other hand be sufficiently thin to be able to effectively dissipate the charges formed. In general, the thickness is 5-200 nm.

Layer 14 consists of the electron acceptor. As for layer 13, the thickness here too should be sufficient to absorb as much light as possible, but, on the other hand, the charges formed must be dissipated effectively. This layer typically likewise has a thickness of 5-200 nm.

Layer 15 is an EBL/ETL and should have a greater optical band gap than the materials of layer 14, in order to reflect the excitons, but nevertheless still to possess sufficient electron transport properties. Suitable compounds are 2,9-dimethyl-4,7-diphenyl-1,10-phenanthroline (BCP), 4,7-diphenyl-1,10-phenanthroline (Bphen), 1,3-bis[2-(2,2′-bipyridin-6-yl)1,3,4-oxadizo-5-yl]benzene (BPY-OXD), ZnO, TiO₂ etc. In the case of an organic layer, this can be provided with an n-dopant whose HOMO has similar or lower energy than the LUMO of the electron transporting layer. Suitable materials are Cs₂CO₃, Pyronin B (PyB), described, for example, in document WO 2003/070822 A2, Rhodamine B, described, for example, in document WO 2005/036667 A1, cobaltocene and the compounds mentioned in document WO 2007/071450 A1. The layer thickness is typically 0-150 nm.

Layer 16 (cathode) consists of a material with a low work function. For example, it comprises metals such as Ag, Al, Ca, Mg or mixtures thereof. The layer thickness is typically 50-1000 nm and should be selected sufficiently such that most light in the wavelength range of 350-1200 nm is reflected.

The customary pressures during the gas phase deposition are between 10⁻⁴ and 10⁻⁹ mbar. The deposition rate varies generally between 0.01 nm/second and 10 nm/second. The temperature of the substrate during the deposition can be varied within a temperature range between −100° C. and 200° C., in order to influence the morphology of the corresponding layer in a controlled manner. The deposition rate is typically between 0.1 nm/second and 2.0 nm/second.

For the deposition of the layers, it is likewise possible to use the process described in WO 1999/025894 A1.

The deposition of the active layer (layer 13 and 14) or the completion of the complete cell, i.e. the deposition of layer 16, may be followed by a heat treatment at from 60° C. to 100° C. for the duration of a few minutes up to several hours, in order to achieve more intimate contact of the layers. For this purpose, it is equally possible to undertake a treatment for the corresponding duration with solvent vapor, for example of toluene, xylene, chloroform, N-methylpyrrolidone, dimethylformamide, ethyl acetate, chlorobenzene and dichloromethane or other solvents.

B) Bulk Heterojunction (BHJ) Construction:

The Structure Comprises the Following Layers:
26 metal electrode (cathode)
(25 optional EBL and/or ETL)
24 ETL
23 electron acceptor-electron donor layer
(22 optional HTL)
21 transparent electrode (anode)

Layers 21 and 22 correspond to layers 11 and 12 from construction A).

Layer 23 can be produced by coevaporation or by solution processing with customary solvents—these have already been discussed above. The proportion of the electron donor in both cases is preferably from 10 to 90% by mass, especially from 20 to 80% by mass. The proportion of electron acceptor is the supplementary proportion to 100% by mass. Here too, the layer must be sufficiently thick that light is absorbed sufficiently, but still sufficiently thin that the charge carriers can be dissipated effectively. Typically, the layer is 5-500 nm thick.

The ETL layer 24 may consist of one or more layers of materials with a low LUMO energy (<3.5 eV). These layers may consist either of organic compounds, such as C60-fullerene, BCP, Bphen or BPY-OXD, or of inorganic compounds, such as ZnO, TiO₂ etc., and are generally between 0 nm-150 nm thick. In the case of organic layers, these may be admixed with the dopants already mentioned above.

Layers 25 and 26 correspond to layers 15 and 16 from construction A). Equally, the deposition rates and aftertreatments correspond to those from construction A).

C) Tandem Cell

The Structure Comprises the Following Layers:
36 metal electrode (cathode)
(additional recombination layers and subcells)
34 2nd subcell
33 recombination layer
32 1st subcell
31 transparent electrode (anode)

Tandem cells comprise two or more subcells, which are usually connected in series, with recombination layers arranged between the individual subcells.

Layer 31 corresponds, in terms of construction, to the aforementioned layers 11 and 21 from constructions A) and B).

Layers 32 and 34 are individual subcells and correspond, in terms of function, to individual cells as under constructions A) and B), with the difference that they do not comprise electrodes 11/16 or 21/26. The subcells therefore consist of layers 12 to 15 of construction A) or 22 to 25 of construction B).

The subcells may, as component K1 or K2, either all comprise merocyanines, or one subcell may comprise one or more merocyanines and the remaining subcells may comprise combinations of other materials, for example C60-fullerene/Znphthalocyanine, oligothiophene (for example DCV5T)/C60-fullerene (as described in WO 2006/092134 A1), or one of the subcells is a dye-sensitized solar cell (DSSC) or a polymer cell, for example in the P3HT/PCBM combination. In addition, both cells of the A) construction and of the B) construction may be present as subcells. In the cases mentioned, the most favorable case is when the combination of the materials/subcells is selected such that the light absorptions of the subcells do not overlap too greatly, but overall cover the spectrum of sunlight, which leads to an increase in the power yield. Taking account of optical interferences which take place in the cell, it is additionally advisable to place a subcell with absorption within a shorter wavelength range close to the electrode 36 than a subcell with absorption in the longer wavelength range.

The recombination layer 33 brings about the recombination of oppositely charged charge carriers in adjacent subcells. The active constituents in the recombination layer may be metal clusters, for example of Ag or Au, or the recombination layer may consist of a combination of highly doped n- and p-conductive layers (as described, for example, in WO 2004/083958 A2).

In the case of use of metal clusters, typically layer thicknesses of 0.5-20 nm are established, and, in the case of the combined doped layers, thicknesses of 5-150 nm. Further subcells may be applied to the subcell 34, in which case further recombination layers, such as layer 33, must likewise be present.

The material for the electrode 36 depends on the polarity of the subcells. In the case of normal polarity, the metals with a low work function already mentioned, for example Ag, Al, Mg and Ca, are useful. In the case of inverted polarity, typically materials with a high work function are used, for example Au, Pt, PEDOT-PSS.

In the case of tandem cells comprising subcells connected in series, the component voltages are additive, but the overall current is limited by the subcell having the lowest current intensity/current density. The individual subcells should therefore be optimized such that their individual current intensities/current strengths have similar values.

Examples of Solar Cells:

All Solar Cells Detailed were Produced According to the Following Steps:

Sublimation of the Merocyanines:

The materials listed at the outset were purified by zone sublimation, the pressure during the entire sublimation having been kept below 1×10⁻⁶ mbar. The yields of the purification by sublimation for each material are listed in table 2.

Materials:

The merocyanines (also referred to hereinafter as Mcy) were used either as obtained from the synthesis or in the purified state, as described above.

NPD: from Alfa Aesar; sublimed once

C60: from Alfa Aesar; sublimed purity (+99.92%); used without further purification

Bphen: from Alfa Aesar; used without further purification

Preparation of the Substrate:

The ITO was applied to the glass substrate by sputtering in a thickness of 140 nm. The specific resistivity was 200 μΩcm and roughness mean square (RMS) was <5 nm. The substrate was treated with ozone under UV light for 20 minutes before the deposition of the further layers.

Production of the Cells:

Cells of constructions A) and B) were prepared under high vacuum (pressure<10⁻⁶ mbar).

The cell of construction A) (ITO/merocyanine/C60/Bphen/Ag) was produced by successive deposition of the merocyanine and C60 onto the ITO substrate. The deposition rate was 0.1 nm/second for both layers. The evaporation temperatures of the merocyanines are listed in table 1. C60 was deposited at 400° C. Once the Bphen layer had been applied, a 100 nm-thick Ag layer was applied by vapor deposition as the top electrode. The cell had an area of 0.031 cm².

For the production of the cells of construction B), (ITO/(merocyanine:C60-1:1 by weight)/C60/Bphen/Ag), the merocyanine and the C60 were coevaporated and applied to the ITO with the same deposition rate of 0.1 nm/second, such that a mass ratio of 1:1 was present in the mixed active layer. The Bphen and Ag layers were identical to the corresponding layers of construction A).

The data of a cell with a BHJ layer on a doped HTL (layer 22) are listed in table 3. NPD and F₄-TCNQ were applied by vapor deposition as the HTL and dopant in a mass ratio of 20:1. The HTL layer improved the open-circuit voltage V_{oc} (oc: open circuit) and provided higher efficiencies.

Analyses:

An AM 1.5 simulator from Solar Light Co. Inc. with a xenon lamp (model 16S-150 V3) was used. The UV range below 415 nm was filtered out and the current-voltage measurements were carried out under ambient conditions. The intensity of the solar simulator was calibrated with a monocrystalline FZ solar cell (Fraunhofer ISE) and the deviation factor was determined to be virtually 1.0.

Results of the Solar Cells:

TABLE 1
Results with merocyanines detailed at the outset in construction A).
The evaporation temperatures Tᵥ are likewise listed.

| | | Mcy | C60 | | | | Effi- |
|---|---|---|---|---|---|---|---|
| Mcy | Tᵥ | thickness | thickness | Voc | Jsc | FF | ciency |
| (ID) | (° C.) | (nm) | (nm) | (mV) | (mA/cm²) | (%) | (%) |
| 492 | 150 | 10 | 40 | 780 | 6.4 | 55 | 2.7 |
| 507 | 175 | 10 | 40 | 620 | 1.5 | 13 | 0.12 |
| 511 | 160 | 10 | 40 | 700 | 5.6 | 57 | 2.2 |
| 528 | 150 | 10 | 40 | 800 | 6.5 | 84 | 2.8 |
| 529 | 180 | 10 | 40 | 740 | 6.4 | 71 | 3.3 |
| 537 | 290 | 40 | 40 | 460 | 0.01 | 18 | 0.001 |
| 538 | 160 | 30 | 40 | 380 | 2.6 | 37 | 0.37 |
| 540 | 220 | 20 | 40 | 620 | 4.7 | 37 | 1.1 |
| 541 | 225 | 10 | 40 | 600 | 3.7 | 24 | 0.5 |
| 546 | 195 | 10 | 40 | 520 | 1.2 | 20 | 0.12 |

TABLE 2
Results with merocyanines detailed at the outset in construction B).
The evaporation temperatures Tᵥ are likewise listed.

| | | BHJ | C60 | | | | Effi- |
|---|---|---|---|---|---|---|---|
| | Yield | thickness | thickness | Voc | Jsc | FF | ciency |
| ID | (%) | (nm) | (nm) | (mV) | (mA/cm²) | (%) | (%) |
| 492 | 55 | 25 | 20 | 760 | 11.2 | 47 | 3.9 |
| 507 | 66 | 25 | 20 | 580 | 4.7 | 38 | 1.0 |
| 511 | — | 25 | 20 | 780 | 11.2 | 50 | 4.3 |
| 528 | 71 | 30 | 20 | 760 | 10.2 | 45 | 3.5 |
| 529 | 56 | 30 | 20 | 740 | 11.3 | 50 | 4.1 |
| 538 | 70 | 20 | 20 | 60 | 3.7 | 39 | 0.08 |
| 540 | — | 20 | 20 | 240 | 7.8 | 39 | 0.7 |
| 541 | 57 | 30 | 20 | 740 | 16.1 | 35 | 4.1 |
| 546 | 44 | 20 | 20 | 550 | 4.4 | 30 | 0.7 |

TABLE 3
Result with Mcy ID 492: C60-BHJ construction on an HTL

| | | Jsc | | Efficiency |
|---|---|---|---|---|
| | Voc (mV) | (mA/cm²) | FF (%) | (%) |
| NPD:F₄TCNQ 10 nm | 900 | 10.5 | 43 | 4.1 |
| No HTL | 740 | 10.9 | 48 | 3.9 |

1. A method for producing at least one photo active layer for an original solar cell or photo detector, the method comprising:
combining a mixture comprising:
K1) at least one compound selected from the group consisting of 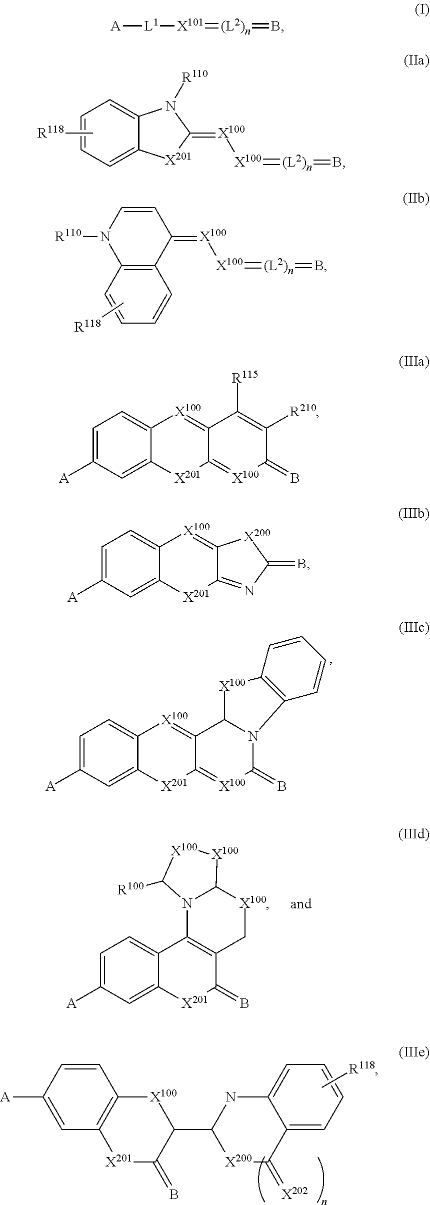
as an electron donor or electron acceptor, wherein
A is NR¹¹⁰₂, where both R¹¹⁰ radicals together with the nitrogen atom to which they are bonded optionally form a five- or six-membered saturated ring, or one of the R¹¹⁰ radicals forms, with the carbon atom of the benzene ring in the α position to the carbon atom which bears the NR¹¹⁰₂ group, a five- or six-membered saturated ring, SR¹¹⁰, or OR¹¹⁰,
B is O, S, N—CN, N—R¹¹⁰, C(CN)₂, C(CO₂R¹¹⁰)₂, C(CN)COR¹¹⁰, C(CN)CO₂R¹¹⁰, C(CN)CONR¹⁰⁰₂, or a moiety selected from the group consisting of 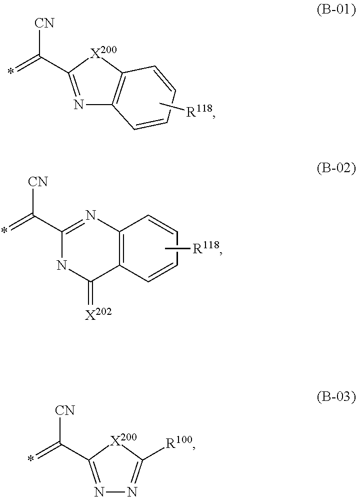
wherein *, in the case of the compounds of formulae I, IIa, and IIb, denotes the bond to L², and, in the case of the compounds of formulae IIIa and IIIb, the bond to the remaining part of the molecule,
L¹ is a divalent aryl or hetaryl radical,
L² is a divalent, optionally singly or multiply fused carbo- or heterocycle which is π-conjugated firstly to B, and secondly via the X¹⁰⁰ or X¹⁰¹ units and the remaining part of the molecule to A, or a 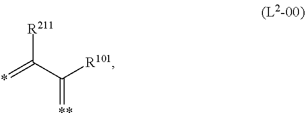
moiety in which * and ** denote the bond firstly to the corresponding X¹⁰¹ or X¹⁰⁰ unit, and secondly to B,
n is 0 or 1,
X¹⁰⁰ is CH, N, or C(CN),
X¹⁰¹ is CH, N, C(CN), or X¹⁰¹ and L² together form a 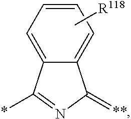
moiety in which * and ** denote the bond firstly to the corresponding L¹ unit, and secondly to B,
X²⁰⁰ is O, S, SO₂, or NR¹¹⁰,
X²⁰¹ is O, S, SO₂, NR¹¹⁰, or CR¹¹¹₂,
X²⁰² is twice H, O, or S,
R¹⁰⁰ is alkyl, C₁-C₆-alkylene-COO-alkyl, C₁-C₆-alkylene-O—CO-alkyl, C₁-C₆-alkylene-O—CO—O-alkyl, cycloalkyl, arylalkyl or aryl,
R¹¹⁰ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, or aryl,
R¹⁰¹ is alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl or hetaryl,
R¹¹¹ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl or hetaryl,
R¹¹⁵ is H, alkyl, partly fluorinated or perfluorinated alkyl, C₁-C₆-alkylene-COO-alkyl, C₁-C₆-alkylene-O—CO-alkyl, C₁-C₆— alkylene-O—CO—O-alkyl, cycloalkyl, arylalkyl, aryl, NHCO—R¹⁰⁰, or N(CO—R¹⁰⁰)₂,
R¹¹⁸ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, OR¹¹⁰, SR¹¹⁰, hetaryl, halogen, NO₂ or CN
R²¹⁰ is H or CN,
R²¹¹ is H, CN, or SCN,
wherein carbon chains of the alkyl and cycloalkyl radicals are optionally interrupted by one or two nonadjacent oxygen atoms,
wherein the R¹¹⁵ and R²¹⁰ radicals in formula IIIa together optionally form a fused benzene ring optionally substituted by R¹¹⁸,
in the case of that X¹⁰⁰ is CH in formula IIId, the R¹⁰⁰ radical optionally forms an optionally R¹¹⁸-substituted benzofusion to this carbon atom, and
aforementioned variables, where they occur more than once, are the same or different,
and
K2) at least one compound which, with respect to component K1), act correspondingly as an electron acceptor or electron donor
in the at least one photoactive layer in an organic solar cell or organic photodetector.

2. The method of claim 1, wherein L² in formulae I, IIa, and IIb is a moiety selected from the group consisting of 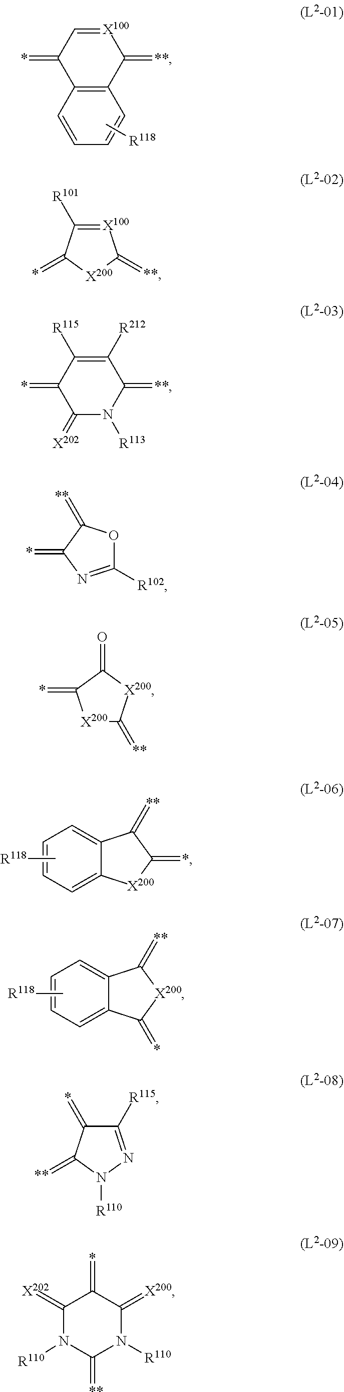 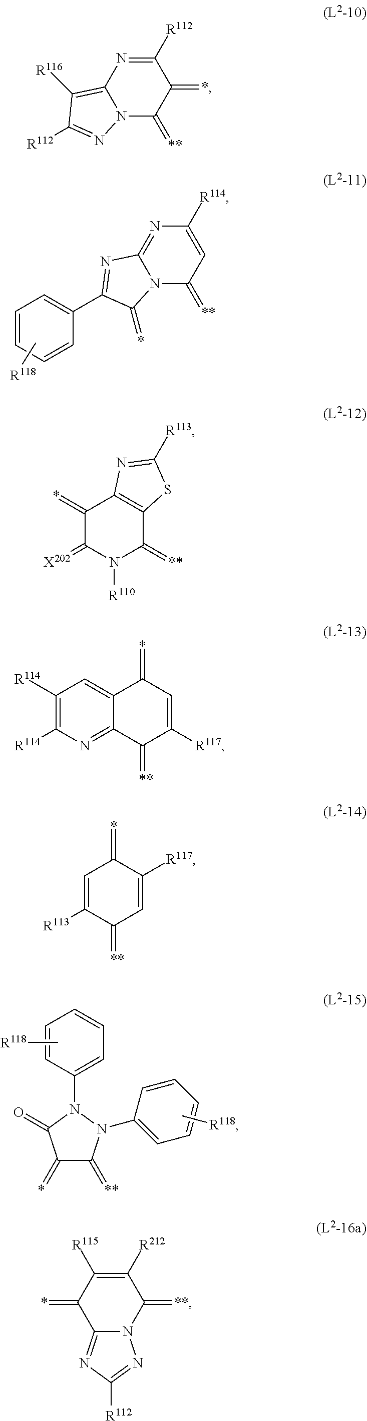 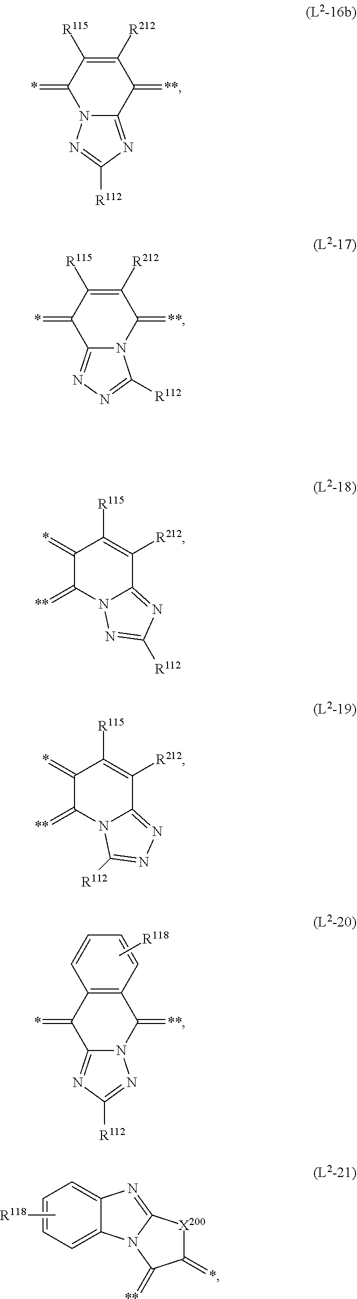 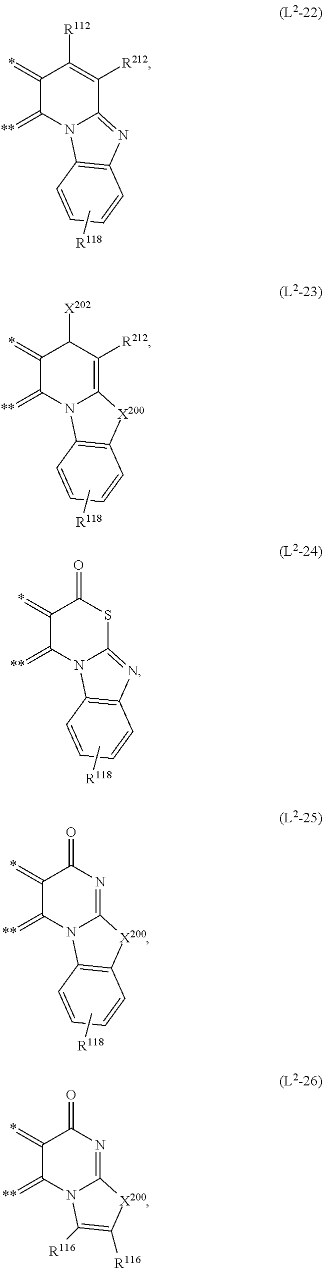 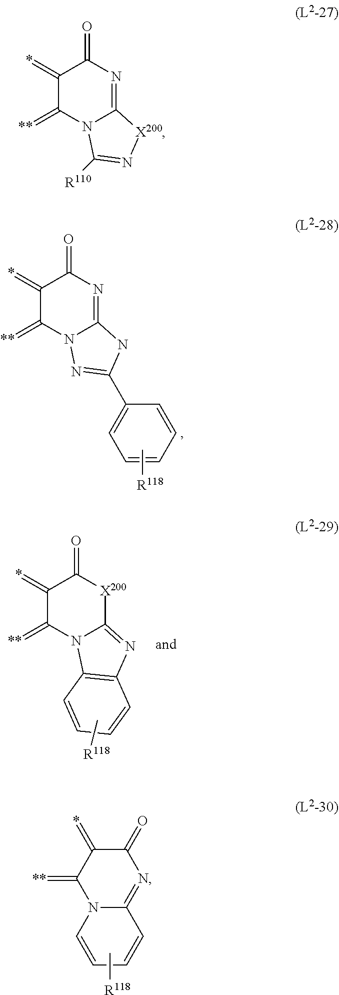
wherein
R¹⁰² is arylalkyl, aryl, or hetaryl,
R¹¹² is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, OR¹¹⁰, or SR¹¹⁰,
R¹¹³ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, hetaryl, NH-aryl, N(aryl)₂, NHCO—R¹⁰⁰, or N(CO—R¹⁰⁰)₂,
R¹¹⁴ is H, H alkyl or partly fluorinated or perfluorinated alkyl, C₁-C₆-alkylene-COO-alkyl, C₁-C₆-alkylene-O—CO-alkyl, or C₁-C₆
R¹¹⁶ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, CO₂R¹¹⁰, or CN
R¹¹⁷ is H, alkyl, C₁-C₆-alkylene-COO-alkyl, C₁-C₆-alkylene-O—CO-alkyl, alkylene-O—CO—O-alkyl, cycloalkyl, arylalkyl, aryl, OR¹¹⁰, SR¹¹⁰ halogen, or hetaryl, and
R²¹² is H, CN, CONR¹¹⁰, or COR¹⁰¹.

3. The method of claim 1, wherein component K2 comprises at least one compound selected from the group consisting of
a) a fullerene, a fullerene derivative,
b) a polycyclic aromatic hydrocarbon, a derivative of a polycyclic aromatic hydrocarbon,
c) a quinone, a quinodimethane, a quinonediimine, a derivative of quinone, a derivative of a quinodimethane, a derivative of a quinonediimine,
d) a phthalocyanine, a subphthalocyanine, a derivative of a phtalocyanine, a derivative of a subphthalocyanine,
e) a porphyrin, a tetraazaporphyrin, a tetrabenzoporphyrin, a derivative of a porphyrin, a derivative of tetraazaporphyrin, a derivative of tetrabenzoporphyrin,
f) a thiophene, an oligothiophene, a fused thiophene, a derivative of a thiophene, a derivative of oligothiophene, a derivative of a fused thiophene,
g) a thiadiazole, a derivative of a thiadiazole,
h) a carbazole, a triarylamine, a derivative of a carbazole, a derivative of a triarylamine,
i) an indanthrone, a violanthrone, a flavanthone, a derivative of an indanthrone, a derivative of a violanthrone, a derivative of a flavanthone
j) a fulvalene, a tetrathiafulvalene, a tetraselenafulvalene, a derivative of a fulvalene, a derivative of a tetrathiafulvalene, and a derivative of a tetraselenafulvalene.

4. The method of claim 1, wherein component K2 comprises at least one selected from the group consisting of a fullerene and a fullerene derivative.

5. The method of claim 1, wherein component K2 comprises at least one fullerene.

6. The method of claim 1, wherein component K2 comprises a C60-fullerene of the formula k2

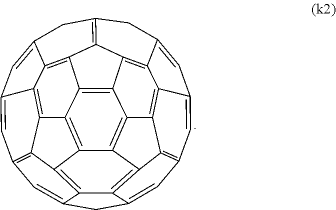

7. The method of claim 1, wherein
component K1 is present in a proportion of from 10 to 90% by mass, and
component K2 is present in a proportion of from 90 to 10% by mass,
wherein the proportions of components K1 and K2, based in each case on the total mass of components K1 and K2, add up to 100% by mass.

8. The method of claim 1, wherein the at least one compound of component K1 and the at least one compound of component K2 are combined in the photoactive layer by depositing them onto a substrate successively, simultaneously, or in alternating sequence, by vacuum sublimation.

9. The method of claim 9, wherein components K1 and K2, after they have been deposited, are present on the substrate in a ratio, wherein
component K1 is present in a proportion of from 10 to 90% by mass, and
component K2 is present in a proportion of from 90 to 10% by mass,
wherein the proportions of components K1 and K2, based in each case on the total mass of components K1 and K2, add up to 100% by mass.

10. An organic solar cell or organic photodetector, comprising at least one photoactive layer produced by the method of claim 1.

11. A mixture, comprising: K1) at least one compound selected from the group consisting of: 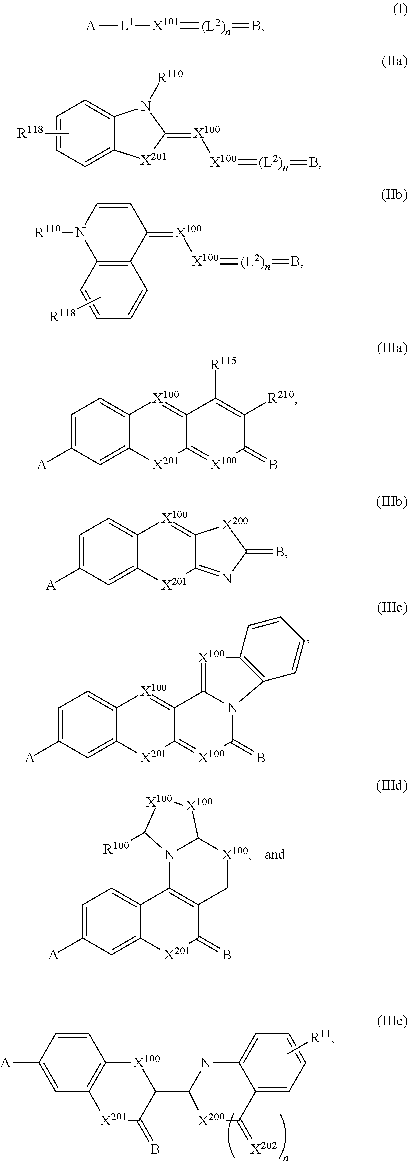
wherein
A is NR¹⁰⁰₂, where both R¹¹⁰ radicals together with the nitrogen atom to which they are bonded optionally form a five- or six-membered saturated ring, or one of the R¹¹⁰ radicals forms, with the carbon atom of the benzene ring in the α position to the carbon atom which bears the NR¹¹⁰₂ group, a five- or six-membered saturated ring, SR¹¹⁰, or OR¹¹⁰,
B is O, S, N—CN, N—R¹¹⁰, C(CN)₂, C(CO₂R¹¹⁰)₂, C(CN)COR¹¹⁰, C(CN)CO₂R¹¹⁰, C(CN)CONR¹⁰⁰₂, or a moiety selected from the group consisting of 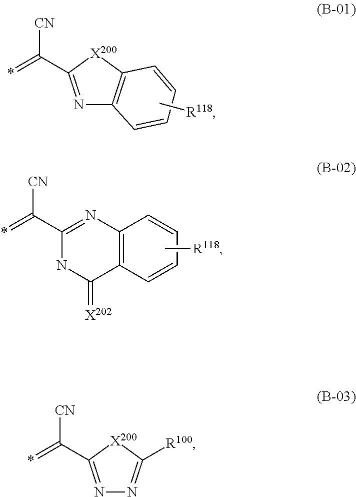
wherein *, in the case of the compounds of formulae I, IIa, and IIb, denotes the bond to L², and, in the case of the compounds of formulae IIIa and IIIb, the bond to the remaining part of the molecule,
L¹ is a divalent aryl or hetaryl radical,
L2 is a divalent, optionally singly or multiply fused carbo- or heterocycle which is π-conjugated firstly to B, and secondly via the X¹⁰⁰ or X¹⁰¹ units and the remaining part of the molecule to A, or a 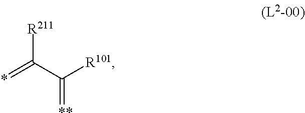
moiety in which * and ** denote the bond firstly to the corresponding X¹⁰¹ or X¹⁰⁰ unit, and secondly to B,
n is 0 or 1,
X¹⁰⁰ is CH, N, or C(CN),
X¹⁰¹ is CH, N, C(CN), or X¹⁰¹ and L² together form a 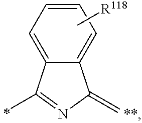
moiety in which * and ** denote the bond firstly to the corresponding L¹ unit, and secondly to B,
X²⁰⁰ is O, S, SO₂, or NR¹¹⁰,
X²⁰¹ is S, SO₂, NR¹¹⁰, or CR¹¹¹₂,
X²⁰² is twice H, O, or S,
R¹⁰⁰ is alkyl, C₁-C₆-alkylene-COO-alkyl, C₁-C₆-alkylene-O—CO-alkyl, C₁-C₆-alkylene-O—CO—O-alkyl, cycloalkyl, arylalkyl or aryl,
R¹¹⁰ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, or aryl,
R¹⁰¹ is alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, or hetaryl,
R¹¹¹ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, or hetaryl,
R¹¹⁵ is H, alkyl, partly fluorinated or perfluorinated alkyl, C₁-C₆-alkylene-COO-alkyl, C₁-C₆-alkylene-O—CO-alkyl, C₁-C₆— alkylene-O—CO—O-alkyl, cycloalkyl, arylalkyl, aryl, NHCO—R¹⁰⁰, or N(CO—R¹⁰⁰)₂,
R¹¹⁸ is H, alkyl, C₁-C₆-alkylene-COO-alkyl, C₁-C₆-alkylene-O—CO-alkyl, C₁-C₆-alkylene-O—CO—O-alkyl, cycloalkyl, arylalkyl, aryl, OR¹¹⁰, SR¹¹⁰, hetaryl, halogen, NO₂, or CN
R²¹⁰ is H or CN,
R²¹¹ is H, CN, or SCN,
wherein carbon chains of the alkyl and cycloalkyl radicals are optionally interrupted by one or two nonadjacent oxygen atoms,
wherein the R¹¹⁵ and R²¹⁰ radicals in formula IIIa together optionally form a fused benzene ring optionally substituted by R¹¹⁸,
in the case of that X¹⁰⁰ is CH in formula IIId, the R¹⁰⁰ radical optionally forms an optionally R¹¹⁸-substituted benzofusion to this carbon atom, and
aforementioned variables, where they occur more than once, are the same or different,
and
K2) at least one at least one compound which, with respect to component K1), acts correspondingly as an electron acceptor or electron donor.

12. The mixture of claim 11, wherein
component K1 is present in a proportion of from 10 to 90% by mass, and
component K2 in a proportion of from 90 to 10% by mass,
wherein the proportions of components K1 and K2, based in each case on the total mass of components K1 and K2, add up to 100% by mass.

13. The method of claim 1, wherein component K2 comprises at least one compound selected from the group consisting of a rylene, a derivative of a rylene, an acene, and a derivate of an acene.

14. The method of claim 1, wherein component K2 comprises at least one compound selected from the group consisting of naphthalene, a derivative of naphthalene, perylene, terrylene, quaterrylene, a derivative of perylene, a derivative of terrylene, a derivative of quaterrylene, anthracene, tetracene, rubrene, pentacene, a derivative of anthracene, a derivative of tetracene, a derivative of rubrene, a derivative of pentacene, pyrene, a derivative of pyrene, coronene, a derivative of coronene, hexabenzocoronene, and a derivative of hexabenzocoronene

15. The method of claim 2, wherein component K2 comprises at least one selected from the group consisting of a fullerene and a fullerene derivative.

16. The method of claim 2, wherein component K2 comprises at least one fullerene.

17. The method of claim 2, wherein component K2 comprises a C60-fullerene of the formula k2

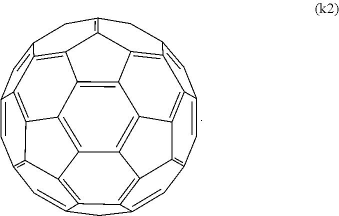

18. The method of claim 1, wherein
component K1 is present in a proportion of from 20 to 80% by mass, and
component K2 is present in a proportion of from 80 to 20% by mass,
wherein the proportions of components K1 and K2, based in each case on the total mass of components K1 and K2, add up to 100% by mass.

19. The method of claim 2, wherein
component K1 is present in a proportion of from 10 to 90% by mass, and
component K2 is present in a proportion of from 90 to 10% by mass,
wherein the proportions of components K1 and K2, based in each case on the total mass of components K1 and K2, add up to 100% by mass.

20. The method of claim 2, wherein
component K1 is present in a proportion of from 20 to 80% by mass, and
component K2 is present in a proportion of from 80 to 20% by mass,
wherein the proportions of components K1 and K2, based in each case on the total mass of components K1 and K2, add up to 100% by mass.
